(19) United States
(12) Patent Application Publication
(10) Pub. No.: US 2015/0093704 A1
(43) Pub. Date: Apr. 2, 2015

(54) RADIATION-SENSITIVE RESIN COMPOSITION, RESIST-PATTERNING METHOD, AND BLOCK COPOLYMER

(71) Applicant: JSR CORPORATION, Tokyo (JP)

(72) Inventor: Hitoshi OSAKI, Tokyo (JP)

(73) Assignee: JSR CORPORATION, Tokyo (JP)

(21) Appl. No.: 14/498,256

(22) Filed: Sep. 26, 2014

(30) Foreign Application Priority Data
Sep. 30, 2013 (JP) 2013-205407

(51) Int. Cl. G03F 7/038; G03F 7/30

(52) U.S. Cl. CPC G03F 7/0388; G03F 7/038; G03F 7/30
USPC 430/285.1; 430/281.1; 430/325; 525/276

(57) ABSTRACT

A radiation-sensitive resin composition includes (A) a block copolymer, and (B) an acid-generating agent. The block copolymer (A) includes a polymer block (I), a polymer block (II), and a moiety contained in the polymer block (I), the polymer block (2), or both thereof. The polymer block (I) includes an acid-dissociable group. The polymer block (II) includes an alkali-dissociable group. The moiety provides water repellency.

### CROSS-REFERENCE TO RELATED APPLICATIONS

The present application claims priority under 35 U.S.C. §119 to Japanese Patent Application No. 2013-205407, filed Sep. 30, 2013. The contents of this application are incorporated herein by reference in their entirety.

### BACKGROUND OF THE INVENTION

1. Field of the Invention

The present invention relates to a radiation-sensitive resin composition, a resist-patterning method, and a block copolymer.

2. Discussion of the Background

Photolithographic technologies of forming a resist pattern using a photoresist composition have been used in the microfabrication field for manufacture of integrated circuit elements and the like. Specifically, resist patterns containing both exposed and unexposed regions have been produced by forming a resist film on a substrate using a photoresist composition, irradiating the resist film via a mask pattern with a short-wavelength radiation ray such as KrF excimer laser (wavelength: 248 nm) or ArF excimer laser (wavelength: 193 nm).

A chemical amplification-type photoresist composition containing an acid-dissociable group-containing component and an acid generator that generates an acid by irradiation with radiation ray has been used as the resist composition (see JP-A No. S59-45439).

On the other hand, recently under the need for reduction in size of resist pattern, the liquid-immersion exposure method (wherein there is a liquid between the resist film and the lens) has been used increasingly frequently as a method of forming a resist pattern having a line width, for example, of about 45 nm. The liquid-immersion exposure method has an advantage that it is possible, even when a light source having the same exposure wavelength is used, to achieve a high resolution similar to that obtained when a shorter-wavelength light source is used.

As the photoresist composition favorable for the liquid-immersion exposure proposed was a radiation-sensitive resin composition containing a highly hydrophobic fluorine atom-containing polymer for suppression of elution of the acid generator and others from the resist film to the liquid-immersion exposure liquid and for improvement of water repellency of the resist film (see WO No. 2007/116664).

Also proposed was a radiation-sensitive resin composition containing a block copolymer containing two kinds of polymer blocks different in fluorine content that can be used favorably for preparation of a resist film by resist-patterning methods including the liquid-immersion exposure (see JP-A No. 2010-230891).

### SUMMARY OF THE INVENTION

According to one aspect of the present invention, a radiation-sensitive resin composition includes (A) a block copolymer, and (B) an acid-generating agent. The block copolymer (A) includes a polymer block (I), a polymer block (II), and a moiety contained in the polymer block (I), the polymer block (2), or both thereof. The polymer block (I) includes an acid-dissociable group. The polymer block (II) includes an alkali-dissociable group. The moiety provides water repellency.

According to another aspect of the present invention, a resist-patterning method includes (1) forming a resist film on a substrate using the radiation-sensitive resin composition; (2) exposing the resist film through liquid; and (3) forming a resist pattern by developing the exposed resist film.

According to further aspect of the present invention, a block copolymer includes a polymer block (I), a polymer block (II), and a moiety contained in the polymer block (I), the polymer block (2), or both thereof. The polymer block (I) includes an acid-dissociable group. The polymer block (II) includes an alkali-dissociable group. The moiety provides water repellency.

### BRIEF DESCRIPTION OF THE DRAWINGS

FIG. 1 is a schematic view illustrating the state of the block copolymer in a resist film formed from the radiation-sensitive resin composition according to an embodiment of the present invention.

### DESCRIPTION OF EMBODIMENTS

An embodiment of the present invention first provides a radiation-sensitive resin composition, comprising (A) a block copolymer containing at least a polymer block (I) having acid-dissociable groups and a polymer block (II) having alkali-dissociable groups and having water-repellency-providing moieties in the polymer block (I) or (II) or both of them (hereinafter, referred to also as “block copolymer (A)”), and (B) an acid-generating agent.

The water-repellency-providing moiety may contain at least one atom selected from the group consisting of fluorine and silicon atoms or only a fluorine atom.

In the radiation-sensitive resin composition according to the embodiment of the present invention, the polymer block (II) may have, as the alkali-dissociable group-containing structure, one or more structures selected from the group consisting of structures represented by the following Formula (f-a), structures represented by the following Formula (f-b), and structures represented by the following Formula (f-c).

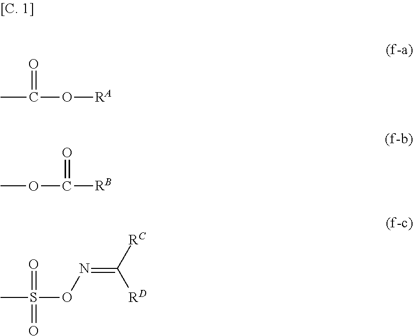

(in Formulae (f-a), (f-b), and (f-c), R^{A}, R^{B}, R^{C}, and R^{D} each independently represent a monovalent hydrocarbon group, in which part or all of the hydrogen atoms may be substituted.)

In the radiation-sensitive resin composition according to the embodiment of the present invention, the polymer block (II) may have structural units represented by the following Formula (2) as the alkali-dissociable group-containing structure.

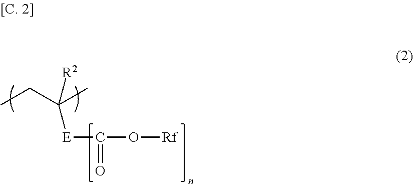

(in Formula (2), R² represents a hydrogen or fluorine atom or a monovalent linear hydrocarbon group having a carbon number of 1 to 4. Part or all of the hydrogen atoms in the linear hydrocarbon group may be substituted with halogen atoms. In Formula (2), E represents a single bond or a (n+1)-valent group and Rf represents a monovalent linear hydrocarbon group or a monovalent aromatic hydrocarbon group. Part or all of the hydrogen atoms in the linear hydrocarbon group and the aromatic hydrocarbon group may be substituted with fluorine atoms. In Formula (2), n is an integer of 1 to 3. However when n is 2 or 3, the multiple groups Rf may be the same as or different from each other.)

In the radiation-sensitive resin composition according to the embodiment of the present invention, the block copolymer (A) may be a diblock copolymer of the polymer blocks (I) and (II).

In the radiation-sensitive resin composition according to the embodiment of the present invention, the block copolymer (A) may have a polymer block (I) content of 15 to 40 mol % and a polymer block (II) content of 60 to 85 mol %.

In the radiation-sensitive resin composition according to the embodiment of the present invention, the block copolymer (A) may have a (meth)acrylate-derived skeleton.

The radiation-sensitive resin composition according to the embodiment of the present invention may have additionally an acid-dissociable group-containing polymer (C) (excluding the polymer corresponding to the block copolymer (A)). The radiation-sensitive resin composition may contain the block copolymer (A) in an amount of 1 to 20 parts by mass with respect to 100 parts by mass of the acid-dissociable group-containing polymer (C).

Another embodiment of the present invention provides a resist-patterning method, comprising (1) a step of forming a resist film on a substrate using the radiation-sensitive resin composition, (2) a step of liquid-immersion exposing the resist film, and (3) a step of forming a resist pattern by developing the liquid-immersion-exposed resist film.

Further, another embodiment of the present invention provides a block copolymer comprising at least a polymer block (I) containing acid-dissociable groups and a polymer block (II) containing alkali-dissociable groups and water-repellency-providing moieties.

It is possible according to the embodiment of the present invention to provide a radiation-sensitive resin composition that can give a favorable resist pattern with fewer development defects.

Hereinafter, favorable embodiments of the present invention will be described in detail. It should be understood that the embodiments below are examples of the typical embodiments of the present invention and the present invention is not limited to the embodiments below.

### [Radiation-Sensitive Resin Composition]

The radiation-sensitive resin composition according to the embodiment of the present invention contains at least “a block copolymer (A)” and “an acid-generating agent (B).” The radiation-sensitive resin composition preferably contains additionally an acid-dissociable group-containing polymer (C) (hereinafter, referred to as “polymer (C)”), an acid diffusion-regulating agent (D), and a solvent (E). Further, the radiation-sensitive resin composition may contain any other components in the range that does not impair the advantageous effects of the present invention.

Hereinafter, the components constituting the radiation-sensitive resin composition according to the present embodiment of the will be described.

### <Block Copolymer (A)>

### [Configuration of Block Copolymer (A)]

The block copolymer (A) contains at least a polymer block (I) having acid-dissociable groups and a polymer block (II) having alkali-dissociable groups and has water-repellency-providing moieties in the polymer block (I) or (II) or both of them.

The “acid-dissociable group” is a polar group such as carboxy group, hydroxyl group, amino group, or sulfo group, of which the hydrogen atom is substituted, i.e., a group that dissociates by action of an acid. The “acid” for use may be an acid generated by photoirradiation from “the acid-generating agent (B)” described below.

Alternatively, the “alkali-dissociable group” is a polar group such as carboxy group, hydroxy group, or sulfo group, of which the hydrogen atom is substituted, i.e., a group that dissociates in the presence of alkali (for example, in 2.38 mass % aqueous tetramethylammonium hydroxide (TMAH) solution at 23° C.).

Hereinafter the alkali-dissociable group will be described more specifically. Generally, the ester bonds in acrylic esters do not dissociate or hardly dissociate under the alkalinity of the developing solutions used in lithographic processes. Accordingly when an acrylate-based monomer is used as the monomer constituting the structural unit of the alkali-dissociable group-containing constitutive monomer, the monomer preferably has two or more ester bonds, from the viewpoint of the dissociation efficiency of the alkali-dissociable group in alkaline developing solution.

Even if the acrylate-based monomer has two or more ester bonds, a normal ester bond does not dissociate easily in the developing solution. Thus, the ester bond preferably has an electron-withdrawing group such as fluorine atom or perfluoroalkyl group for facile dissociation.

It is also preferable for increased contribution to the dissociation efficiency that the electron-withdrawing group is introduced not to the group derived from the alcohol of ester bond but to the group derived from the carboxylic acid of ester bond.

The block copolymer (A) contained in the radiation-sensitive resin composition according to the embodiment of the present invention is characteristically a block copolymer having a polymer block (I) having acid-dissociable groups and a polymer block (II) having alkali-dissociable groups.

Most of the polymers contained in radiation-sensitive resin compositions in prior art were random copolymers, because they are readily prepared. Methods of adjusting the kinds and the blending rate of the monomers for the copolymer are generally used for modification of their properties.

However, based on an idea different from that for traditional technologies, the inventors have found that regulation of the sequential structure of the monomers constituting the copolymer contributes to reduction of development defects and succeeded to form a resist pattern more favorable than that formed by using a conventional radiation-sensitive resin composition. Hereinafter, the embodiment of the present invention will be described in detail with reference to drawings.

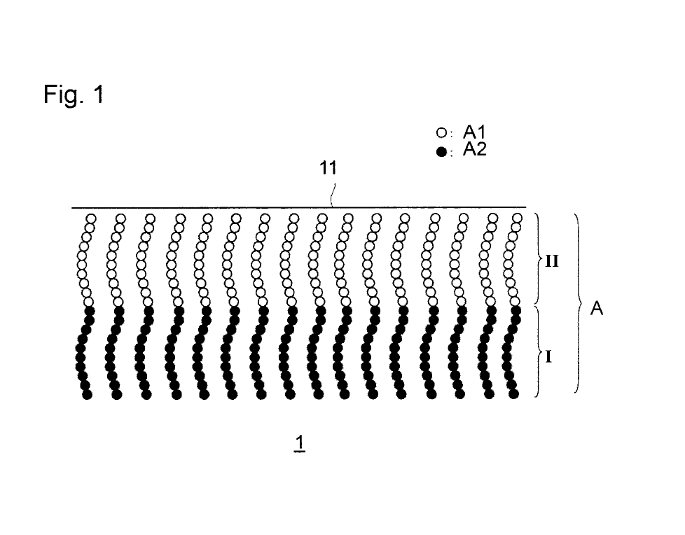

FIG. 1 is a schematic diagram illustrating schematically the state of the block copolymer (A) in a resist film 1 formed from the radiation-sensitive resin composition according to the embodiment of the present invention. As will be described below, in the resist film 1 formed from the radiation-sensitive resin composition, the block copolymer (A) is present locally on the surface side 11 of the resist film 1. The block copolymer (A) is configured to have a polymer block (I) having repeating structural units (A1) containing an acid-dissociable group and a polymer block (II) having repeating structural units (A2) containing an alkali-dissociable group. As shown in FIG. 1, in the block copolymer (A), which is present locally on the surface side 11 of the resist film 1, multiple polymer blocks (I) and multiple polymer blocks (II) come close to each other respectively by interaction between the polymer chains, orienting themselves in the state in which the polymer block (II) is directed toward the surface side. In this way, the resist film becomes more resistant to the liquid-immersion exposure liquid during liquid-immersion exposure and the reactivity of the developing solution becomes improved during development using an alkaline developing solution. It is thus possible to reduce development defects of the resist film 1 after development and to form a favorable resist pattern.

In addition, the radiation-sensitive resin composition according to the embodiment of the present invention becomes more resistant to development defects according to the sequential structure of the monomers constituting the block copolymer (A) contained therein. Thus when the monomers used are structural units (A1) having an acid-dissociable group and structural units (A2) having an alkali-dissociable group, it is possible to reduce the development defects sufficiently without modification of their specific structures.

Further, the block copolymer (A) has water-repellency-providing moieties in the polymer block (I) and/or the polymer block (II). The water-repellency-providing moiety is an atom or a group that make the block copolymer (A) water-repellent, as it is contained in the chain of the polymer block (I) and/or polymer block (II). Such a water-repellency-providing moiety preferably contains a fluorine atom and/or a silicon atom, and more preferably a fluorine atom.

By providing the polymer block (I) and/or polymer block (II) of the block copolymer (A) with water-repellency-providing moieties, it would be possible to make the block copolymer (A) distributed more effectively to the surface side of the resist film, when a resist film is formed from the radiation-sensitive resin composition containing the block copolymer (A). It seems that the block copolymer (A) provides the surface side of the resist film with water repellency, as it is oriented locally to the surface side of the resist film.

The water-repellency-providing moieties are preferably present at least in the polymer block (II) of the block copolymer (A). In the case that the polymer block (II) contains the water-repellency-providing moieties, it seems that the polymer block (II) is oriented to the surface side of the resist film more easily when a resist film is formed. When the polymer block (II) is oriented to the surface side of the resist film, the surface side of the resist film seems to show water repellency more easily.

It seems, as a result, that it becomes possible to suppress elution of the acid generator, the acid diffusion-regulating agent, and others into the liquid-immersion exposure liquid during liquid immersion exposure and increase the receding contact angle between the resist film and the liquid-immersion exposure liquid, permitting high-speed scan exposure without residual of water droplets. In addition, the resist film becomes more water-repellent, reducing the development defects derived from the liquid-immersion exposure liquid such as water marks.

In this way, it is possible by using a block copolymer (A) having water-repellency-providing moieties in the polymer block (II) to reduce development defects of the resist film and contribute to preparation of favorable resist patterns. It is thus not needed to additionally form an overcoat film for separation of the resist film from the liquid-immersion exposure liquid and thus, the radiation-sensitive resin composition according to the embodiment of the present invention can be used favorably in the liquid-immersion exposure method.

The water-repellency-providing moieties may be present in the polymer block (I) or both in the polymer blocks (I) and (II). When the water-repellency-providing moieties are present both in the polymer blocks (I) and (II), the water-repellency-providing moieties are preferably present more in the polymer block (II) than in the polymer block (I). It seems in this way that the polymer block (II) is oriented more easily to the surface side of the resist film.

The water-repellency-providing moieties may be present in the polymer (C) described below, but in this case, the water-repellency-providing moieties are preferably contained more in the block copolymer (A) than in the polymer (C). It seems in this way that the block copolymer (A) is distributed more effectively to the surface side of the resist film.

When fluorine atoms are contained in the water-repellency-providing moiety, the fluorine atoms are preferably present in the structural units (A2) having an alkali-dissociable group in the polymer block (II) and more preferably in the regions close to the bonds that are dissociated by addition of an alkaline developing solution. The regions close to the bonds that are dissociated by addition of an alkaline developing solution are, for example, when the structural unit (A2) has an ester bond as will be described below, α- and β-positions of the carbonyl carbon of the ester bond and α- and β-positions of the group derived from alcohol of the ester bond. The fluorine atom, when present at such a position, gives an alkali-dissociable group that dissociated easily by addition of an alkaline developing solution because of the electron-withdrawing property thereof.

When fluorine atoms are present in the polymer block (II), the fluorine atom content in the polymer block (II) is preferably 25 to 45 mass %, more preferably 20 to 40 mass %, and yet more preferably 15 to 35 mass %, with respect to 100 mass % of the total amount of the block copolymer (A).

When fluorine atoms are present in the polymer block (I), the fluorine atom content in the polymer block (I) is preferably more than 0 mass % and 30 mass % or less, more preferably more than 0 mass % and 10 mass % or less, and yet more preferably more than 0 mass % and 5 mass % or less, with respect to 100 mass % of the total amount of the block copolymer (A).

The fluorine atoms are preferably contained in a greater amount in the polymer block (II) than in the polymer block (I).

The content of the polymer block (I) in the block copolymer (A) is preferably 5 to 50 mol %, more preferably 10 to 45 mol %, and yet more preferably 15 to 40 mol %.

The content of the polymer block (II) in the block copolymer (A) is preferably 50 to 95 mol %, more preferably 55 to 90 mol %, and yet more preferably 60 to 85 mol %.

The skeletons constituting the polymer block (I) and the polymer block (II) in the block copolymer (A) are, similarly to the polymer (C) described below, “polymers containing alicyclic skeletons such as norbornane rings in the main chain”, “polymers having norbornane rings and maleic anhydride derivatives in the main chain”, “polymers having both norbornane rings and (meth)acrylate-derived skeletons in the main chain”, “polymers having norbornane rings, maleic anhydride derivatives, and (meth)acrylate-derived skeletons in the main chain”, “polymers having (meth)acrylate-derived skeletons in the main chain”, and the like.

In particular, the skeleton constituting the polymer blocks (I) and (II) is preferably a “polymer containing (meth)acrylate-derived skeletons,” and more preferably, a “polymer containing (meth)acrylate-derived skeletons in the main chain.” Thus, the block copolymer (A) preferably contains (meth)acrylate-derived skeletons.

The sequence of the polymer block (I) and the polymer block (II) constituting the block copolymer (A) is not particularly limited. The sequence of the polymer blocks (I) and (II) is, for example, a diblock copolymer of (I)-(II), a triblock copolymer of (I)-(II)-(I) or (II)-(I)-(II), a tetrablock copolymer of (I)-(II)-(I)-(II) or (II)-(I)-(II)-(I), a pentablock copolymer of (I)-(II)-(I)-(II)-(I) or (II)-(I)-(II)-(I)-(II) or the like. The block copolymer (A) may be a multiblock copolymer having six or more polymer blocks (I) and (II).

Among the combinations of the polymer blocks (I) and (II) of the block copolymer (A), a diblock copolymer of (I)-(II) and a triblock copolymer of (II)-(I)-(II) are preferable. It seems that the polymer block (II) is oriented to the surface side of the resist film more easily in such a block copolymer (A). If the production process and others are taken into consideration, the block copolymer (A) is more preferably a diblock copolymer of polymer blocks (I)-(II).

Hereinafter, each of the polymer block structural units for the block copolymer (A) will be described more in detail.

### [Polymer Block (I)]

### [Structural Unit (A1)]

The polymer block (I) in the block copolymer (A) has repeating structural units (A1) having an acid-dissociable group. The polymer block (I) may be made only of the structural units (A1).

The structural unit (A1) may be any structural unit, if it has an acid-dissociable group, and the structure, position, number, and others of the acid-dissociable group are not particularly limited.

The structural unit (A1) is preferably a structural unit (A1-1) represented by the following Formula (1).

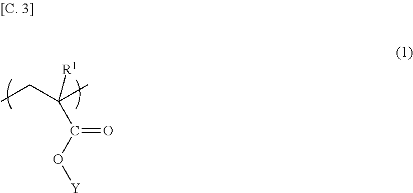

The structural unit (A1-1), when contained as the structural unit (A1), makes the acid-dissociable group dissociate easily and, as a result, improves the pattern shape of the resist pattern formed from the radiation-sensitive resin composition. In addition, the polymer block (I) having the structural units (A1-1) can be synthesized relatively easily.

In Formula (1) above, R¹ represents a hydrogen atom, a fluorine atom, or a monovalent linear hydrocarbon group having a carbon number of 1 to 4, and part or all of the hydrogen atoms in the linear hydrocarbon group may be substituted with halogen atoms.

Y in Formula (1) above is an acid-dissociable group represented by the following Formula (Y-1):

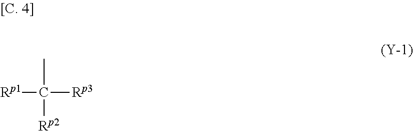

In Formula (Y-1) above, R^{p1} is a monovalent linear hydrocarbon group having a carbon number of 1 to 5 or a monovalent aliphatic cyclic hydrocarbon group having a carbon number of 4 to 20.

In Formula (Y-1) above, R^{p2} and R^{p3} each independently represent a monovalent linear hydrocarbon group having a carbon number of 1 to 5 or a monovalent aliphatic cyclic hydrocarbon group having a carbon number of 4 to 20, or R^{p2} and R^{p3} may bind to each other, forming with their carbon atoms a bivalent aliphatic cyclic hydrocarbon group having a carbon number of 4 to 20.

In Formula (1) above, the monovalent linear hydrocarbon group having a carbon number of 1 to 4 represented by R¹ is, for example, a monovalent saturated linear hydrocarbon group, an unsaturated linear hydrocarbon group, or the like. The monovalent linear hydrocarbon group may be a straight- or branched-chain group.

The halogen atom substituting the hydrogen atoms in the linear hydrocarbon group represented by R¹ may be, for example, a fluorine atom, a chlorine atom, a bromine atom, or an iodine atom.

R¹ above is preferably a hydrogen or fluorine atom or a methyl or trifluoromethyl group, more preferably a methyl or trifluoromethyl group, and still more preferably a methyl group.

The monovalent linear hydrocarbon group having a carbon number of 1 to 5 represented by R^{p1}, R^{p2}, and R^{p3} in Formula (Y-1) above is, for example, a monovalent saturated linear hydrocarbon group or an unsaturated linear hydrocarbon group. The monovalent linear hydrocarbon group may be a straight- or branched-chain group.

Each of R^{p1}, R^{p2}, and R^{p3} above is preferably a monovalent saturated linear hydrocarbon group, more preferably a methyl, ethyl, n-propyl, i-propyl, n-butyl, or n-pentyl group, and still more preferably a methyl, ethyl, i-propyl, or n-pentyl group.

The monovalent aliphatic cyclic hydrocarbon group having a carbon number of 4 to 20 represented by R^{p1}, R^{p2}, or R^{p3} in Formula (Y-1) above is, for example, a monovalent monocyclic saturated cyclic hydrocarbon group, a monocyclic unsaturated cyclic hydrocarbon group, a polycyclic saturated cyclic hydrocarbon group, or a polycyclic unsaturated cyclic hydrocarbon group.

Typical examples of the monovalent monocyclic saturated cyclic hydrocarbon groups include cyclobutyl, cyclopentyl, cyclohexyl, cycloheptyl, cyclooctyl, and the like.

Typical examples of the monovalent monocyclic unsaturated cyclic hydrocarbon groups include cyclobutenyl, cyclopentenyl, cyclohexenyl, and the like.

Typical examples of the monovalent polycyclic saturated cyclic hydrocarbon groups include norbornyl, adamantyl, tricyclodecyl, tetracyclododecyl, and the like.

Typical examples of the monovalent polycyclic unsaturated cyclic hydrocarbon groups include norbornenyl, tricyclodecenyl, and the like.

Among the groups above, a monovalent monocyclic saturated cyclic hydrocarbon group or a monovalent polycyclic saturated cyclic hydrocarbon group is preferable, a cyclopentyl, cyclohexyl, norbornyl, or adamantyl group is more preferable, and a cyclohexyl or adamantyl group is still more preferable.

The bivalent aliphatic cyclic hydrocarbon group formed by binding R^{p2} and R^{p3} to each other with their carbon atoms is, for example, a bivalent monocyclic saturated cyclic hydrocarbon group, a monocyclic unsaturated cyclic hydrocarbon group, a polycyclic saturated cyclic hydrocarbon group, or a polycyclic unsaturated cyclic hydrocarbon group.

Typical examples of the bivalent monocyclic saturated cyclic hydrocarbon groups include cyclobutandiyl, cyclopentandiyl, cyclohexandiyl, cycloheptandiyl, cyclooctandiyl, and the like.

Typical examples of the bivalent monocyclic unsaturated cyclic hydrocarbon groups include cyclobutendiyl, cyclopentendiyl, cyclohexendiyl, and the like.

Typical examples of the bivalent polycyclic saturated cyclic hydrocarbon groups include norbornandiyl, adamantandiyl, tricyclodecandiyl, tetracyclododecandiyl, and the like.

Typical examples of the bivalent polycyclic unsaturated cyclic hydrocarbon groups include norbornendiyl, tricyclodecandiyl, tetracyclododecandiyl, and the like.

Among the groups above, a bivalent monocyclic saturated cyclic hydrocarbon group or a bivalent polycyclic saturated cyclic hydrocarbon group is preferable, a cyclopentandiyl, cyclohexandiyl, cyclooctandiyl, norbornandiyl, or adamantandiyl group is more preferable; and a cyclopentandiyl or adamantandiyl group is still more preferable.

Typical examples of the structural units (A1-1) described above include the structural units represented by the following Formulae (1-1) to (1-4) and the like.

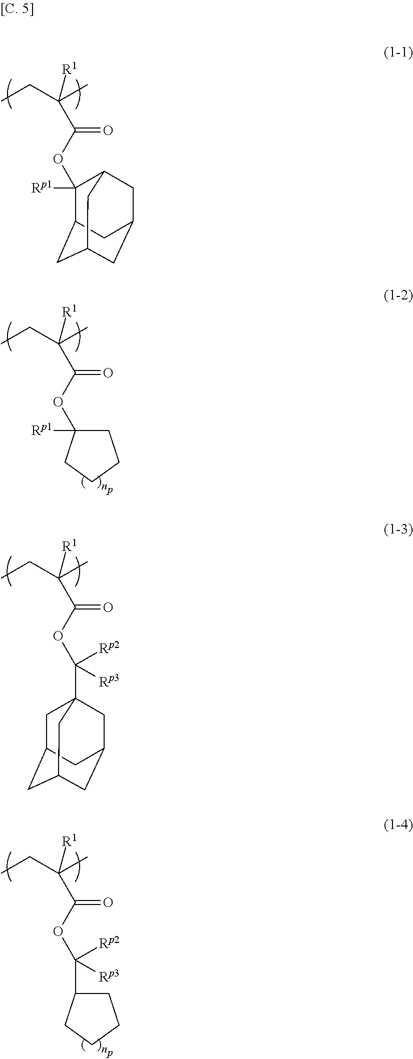

In Formulae (1-1) to (1-4) above, R¹ is the same as R¹ in Formula (1) above, and R^{p1}, R^{p2}, and R^{p3} are the same as those in Formula (Y-1) above. Each nₚ in Formulae (1-1) and (1-4) is independently an integer of 1 to 4.

Typical examples of the structural units represented by Formulae (1-1) to (1-4) above include, for example, structural units represented by the following Formulae ([C. 6] and [C. 7]) and the like.

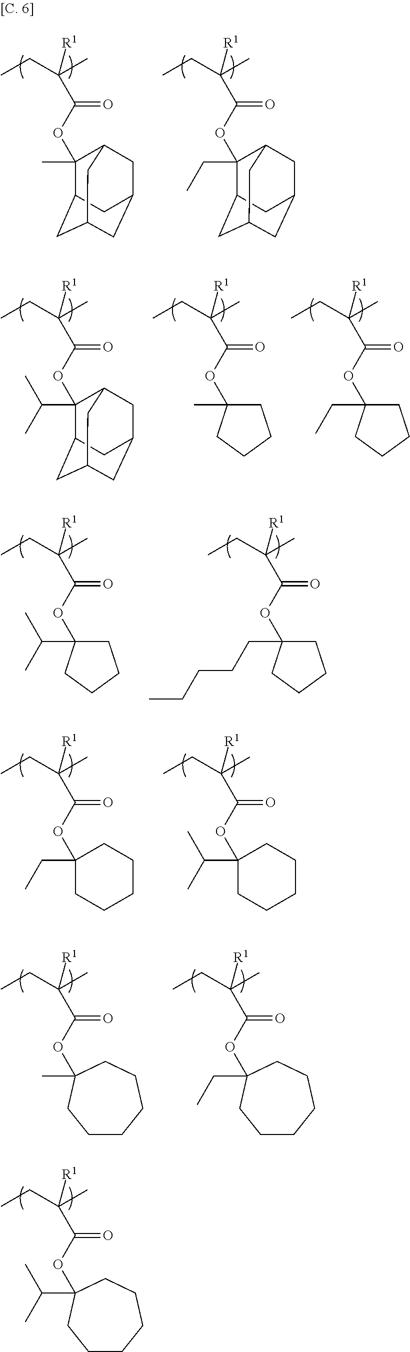

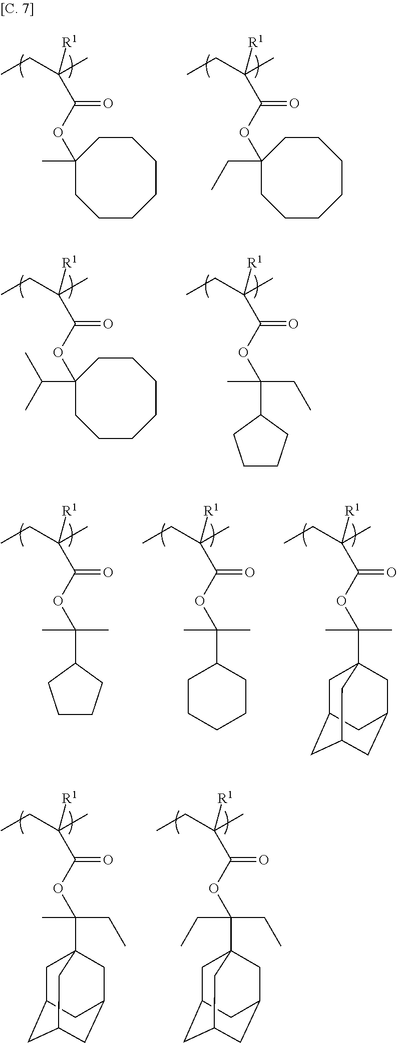

Among the structural units shown in the typical examples of the structural units (A1-1), structural units represented by Formula (1-1) and structural units represented by Formula (1-2) are preferable for improvement of the dissociation efficiency of the acid-dissociable group and also of the pattern shape of the resist pattern obtained from the radiation-sensitive resin composition. Similarly, the structural unit (A1-1) is preferably a structural unit derived from 1-alkyl-substituted-1-cyclopentyl (meth)acrylate, more preferably a structural unit derived from 1-ethyl-1-cyclopentyl (meth)acrylate, 1-isopropyl-1-cyclopentyl (meth)acrylate, or 1-n-pentyl-1-cyclopentyl (meth)acrylate.

### (Content of Structural Units (A1))

The content of the structural units (A1) in the block copolymer (A) is preferably 2.5 to 50 mol %, more preferably 7 to 45 mol %, and still more preferably 8 to 40 mol %, with respect to the total structural units constituting the block copolymer (A).

Alternatively, the content of the structural units (A1) in the polymer block (I) is preferably 50 to 100 mol %, more preferably 70 to 100 mol %, and still more preferably 80 to 100 mol %, with respect to the total structural units constituting the polymer block (I). The structural units (A1), if contained in the amount described above, can reduce development defects in the resist pattern formed from the radiation-sensitive resin composition more effectively.

### [Polymer Block (II)]

### [Structural Unit (A2)]

The polymer block (II) in the block copolymer (A) has repeating structural units (A2) containing an alkali-dissociable group. The polymer block (II) may contain only the structural units (A2). When the polymer block (II) has the water-repellency-providing moieties described above, the water-repellency-providing moieties may be contained in the structural units (A2) or in other structural units.

The alkali-dissociable group in the structural unit (A2) is not particularly limited, if it is a group having such a property. The alkali-dissociable group is, for example, a structure having a polar group such as a carboxy, hydroxy, or sulfo group, of which the hydrogen atom is substituted. The polymer block (II) preferably has one or more structures selected from the structures represented by the following Formulae (f-a), (f-b), and (f-c), as such structures having an alkali-dissociable group.

The structure represented by the following Formula (f-a) is a structure wherein the polar group is a carboxy group and the alkali-dissociable group is R^{A}.

The structure represented by the following Formula (f-b) is a structure wherein the polar group is a hydroxy group and the alkali-dissociable group is —C(═O)R^{B}.

The structure represented by the following Formula (f-c) is a structure wherein the polar group is a sulfo group and the alkali-dissociable group is —N═CR^{C}R^{D}.

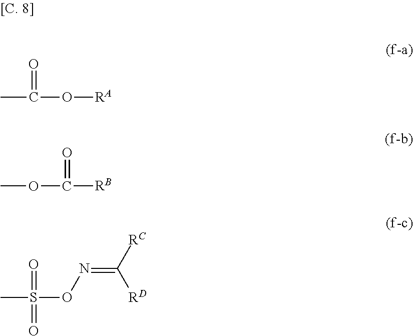

In Formulae (f-a), (f-b), and (f-c) above, R^{A}, R^{B}, R^{C}, and R^{D} each independently represent a monovalent hydrocarbon group and part or all of the hydrogen atoms in the hydrocarbon group may be substituted.

Examples of the “monovalent hydrocarbon groups,” of which part or all of the hydrogen atoms in the hydrocarbon group may be substituted, include monovalent linear hydrocarbon groups, monovalent aliphatic cyclic hydrocarbon groups, monovalent aromatic hydrocarbon groups, and the like. The phrase “may be substituted” means that the hydrocarbon group may have a substituent, as part or all of the hydrogen atoms in the hydrocarbon group is substituted with an atom or a group other than hydrogen atom. Examples of the substituent groups include halogen atoms such as fluorine, chlorine, bromine, and iodine, hydroxy, amino, mercapto, carboxy, cyano, alkyl, alkoxy, acyl, acyloxy, and the like. Among these substituent groups, a fluorine atom is preferable.

The alkali-dissociable group is preferably a group having a fluorine atom. The alkali-dissociable group having a fluorine atom shows favorable dissociation efficiency due to the electron-withdrawing property of the fluorine atom. In such a radiation-sensitive resin composition containing the block copolymer (A), the alkali-dissociable group would show a higher dissociation reaction rate during alkali development. After dissociation of the alkali-dissociable groups, the block copolymer (A) has a lower fluorine atom-content and gives a resist film with increased surface hydrophilicity, thus reducing generation of development defects.

Favorable examples of the fluorine atom-containing groups include fluorine atom-containing linear hydrocarbon groups, fluorine atom-containing aliphatic cyclic hydrocarbon groups, fluorine atom-containing aromatic hydrocarbon groups, and the like. Such a fluorine atom-containing group, if used as the alkali-dissociable group, would dissociate readily by addition of an alkaline developing solution.

The polymer block (II) preferably contains structural units (A2-i) represented by the following Formula (2) as the structural units (A2) forming the polymer block (II). The block copolymer (A) having a polymer block (II) of repeating structural units (A2-i) can be synthesized readily using the monomer giving the structural units (A2-i).

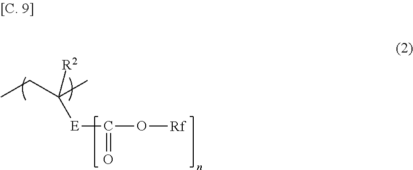

In Formula (2) above, R² represents a hydrogen or fluorine atom or a monovalent linear hydrocarbon group having a carbon number of 1 to 4. Part or all of the hydrogen atoms in the linear hydrocarbon group may be substituted with halogen atoms. In Formula (2) above, E represents a single bond or a (n+1)-valent group and Rf represents a monovalent linear hydrocarbon group or a monovalent aromatic hydrocarbon group. Part or all of the hydrogen atoms in the linear hydrocarbon group and the aromatic hydrocarbon group may be substituted with fluorine atoms. In Formula (2) above, n is an integer of 1 to 3. However when n is 2 or 3, the multiple groups Rf may be the same as or different from each other.

The monovalent linear hydrocarbon group represented by R² above is, for example, a group similar to the monovalent linear hydrocarbon group represented by R¹ of Formula (1), which was explained in description of the polymer block (I) above.

The halogen atom-substituted linear hydrocarbon group represented by R² above is, for example, a group similar to the halogen atom-substituted linear hydrocarbon group represented by R¹ of Formula (1), which was explained in description of the polymer block (I) above.

The group R² above is, among these groups, preferably a hydrogen or fluorine atom or a methyl or a trifluoromethyl group, more preferably a methyl or trifluoromethyl group, and still more preferably a methyl group.

The bivalent to quadrivalent group represented by E above is, for example, a hydrocarbon group from which 2 to 4 hydrogen atoms are eliminated. Examples of the hydrocarbons include straight- or branched-chain saturated hydrocarbons, straight- or branched-chain unsaturated hydrocarbons, monocyclic saturated hydrocarbons, monocyclic unsaturated hydrocarbons, polycyclic saturated hydrocarbons, polycyclic unsaturated hydrocarbons, and aromatic hydrocarbons.

Typical examples of the straight- or branched-chain saturated hydrocarbons include methane, ethane, propane, butane, pentane, hexane, octane, decane, hexadecane, icosane, and the like.

Typical examples of the straight- or branched-chain unsaturated hydrocarbons include ethylene, propylene, butene, pentene, hexene, octene, decene, tetradecene, propyne, hexyne, butadiene, hexadiene, decadiene, hexadiyne, decadiyne, and the like.

Typical examples of the monocyclic saturated hydrocarbons include cyclopropane, cyclobutane, cyclopentane, cyclohexane, cyclooctane, cyclodecane, and the like.

Typical examples of the monocyclic unsaturated hydrocarbons include cyclobutene, cyclopentene, cyclohexene, cyclooctene, cyclodecene, cyclododecyne, cyclopentadiene, cyclohexadiene, cyclodecadiene, cyclodecadiyne, and the like.

Typical examples of the polycyclic saturated hydrocarbons include bicyclo[2.2.1]heptane, bicyclo[2.2.2]octane, tricyclo[5.2.1.0^{2,6}]decane, tricyclo[3.3.1.1^{3,7}]decane (adamantane), tetracyclo[6.2.1.1^{3,6}0.0^{2,7}]dodecane, and the like.

Typical examples of the polycyclic unsaturated hydrocarbons include bicyclo[2.2.1]heptene, bicyclo[2.2.2]octene, tricyclo[5.2.1.0^{2,6}]decene, tricyclo[3.3.1.1^{3,7}]decene, tetracyclo[6.2.1.1^{3,6}0.0^{2,7}]dodecene, and the like.

Typical examples of the aromatic hydrocarbons include benzene, naphthalene, anthracene, phenanthrene, pyrene, toluene, xylene, trimethylbenzene, ethylbenzene, cumene, methylnaphthalene, dimethylnaphthalene, durene, and the like.

Among the compounds above, hydrocarbon groups obtained eliminating 2 to 4 hydrogen atoms respectively from straight- and branched-chain saturated hydrocarbons having a carbon number of 1 to 8, monocyclic saturated hydrocarbons having a carbon number of 5 to 10, polycyclic saturated hydrocarbons having a carbon number of 7 to 12, linear unsaturated hydrocarbon having a carbon number of 2 to 6, and aromatic hydrocarbon having a carbon number of 6 to 15 are preferable.

The group E above may have, at the terminal or other position, for example, an ether, carbonyl, ester, amide, urethane, urea, carbonate, imino, and/or thioether group, and a heterocyclic ring such as lactone ring containing these groups may also be formed.

The group E above may have one or more substituents. Examples of the substituent groups include halogen atoms such as fluorine and chlorine; —R^{p1}, —R^{p2}—O—R^{p1}, —R^{p2}—CO—R^{p1}, —R^{p2}—CO—OR^{p1}, —R^{p2}—O—CO—R^{p1}, —R^{p2}—OH, —R^{p2}—CN, —R^{p2}—COOH, and the like. Here, R^{p1} above is a monovalent linear saturated hydrocarbon group having a carbon number of 1 to 10, a monovalent aliphatic cyclic saturated hydrocarbon group having a carbon number of 3 to 20, or a monovalent aromatic hydrocarbon group having a carbon number of 6 to 30. The group R^{p2} above is a single bond, a bivalent linear saturated hydrocarbon group having a carbon number of 1 to 10, a bivalent aliphatic cyclic saturated hydrocarbon group having a carbon number of 3 to 20, or a bivalent aromatic hydrocarbon group having a carbon number of 6 to 30. Here, part or all of the hydrogen atoms in the linear saturated hydrocarbon group, the aliphatic cyclic saturated hydrocarbon group, and the aromatic hydrocarbon group of R^{p1} and R^{p2} may be substituted with fluorine atoms.

The group E above is, for example, a bivalent to quadrivalent group represented by the following Formulae (E-1) and (E-2).

[C. 10]

—R^{x}Q-R^{y}*)ₙ (E-1)

[C. 11]

—R^{y}-Q-R^{x}*)ₙ (E-2)

In Formulae (E-1) and (E-2), R^{x} represents a (n+1)-valent hydrocarbon group or a lactone-containing group. RY represents a single bond or a bivalent hydrocarbon group. Q represents a single bond, an ether, carbonyl, ester, amide, urethane, urea, carbonate, imino, or thioether group. n is an integer of 1 to 3. * indicates the binding site to the carbonyl carbon in Formula (2). In Formula (E-1) above, when n is 2 or 3, multiple groups Q and RY may be the same as or different from each other.

The (n+1)-valent hydrocarbon group represented by R^{x} above is, for example, a group similar to the (n+1)-valent hydrocarbon group exemplified in description of the group E.

The (n+1)-valent lactone-containing group represented by R^{x} above is, for example, a group obtained by eliminating (n+1) hydrogen atoms from a monocyclic lactone such as butyrolactone or a polycyclic lactone such as norbornane lactone.

The bivalent hydrocarbon group represented by RY above is, for example, a group similar to the bivalent hydrocarbon group (i.e., (n+1)-valent hydrocarbon group, wherein n is 1) exemplified in description of the group E.

The group Q is preferably an ether, carbonyl, or ester group, from the viewpoint of productivity in producing the monomer giving the structural unit (A2).

The group E represented by Formula (E-1) is, for example, a group represented by the following Formulae (E-1-1) to (E-1-6).

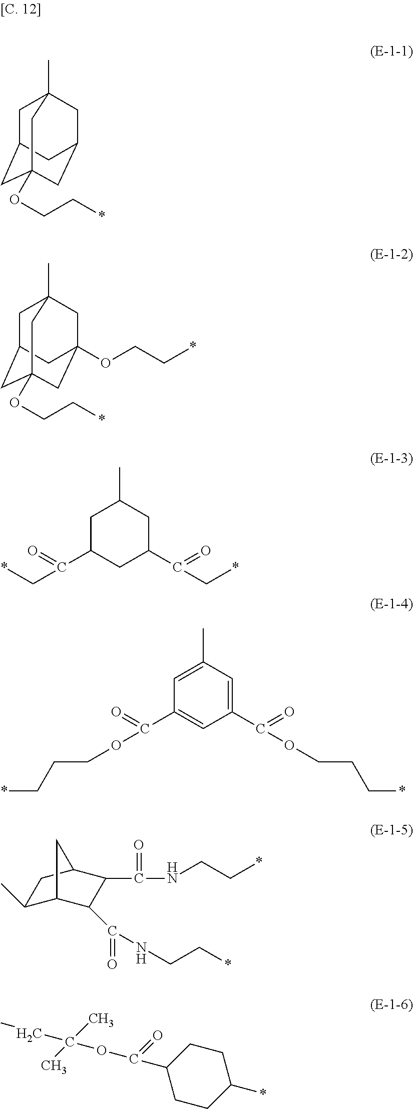

In Formulae (E-1-1) to (E-1-6) above, * is the same as that in Formula (E-1).

Among the groups of Formulae (E-1-1) to (E-1-6), the groups represented by the Formulae (E-1-1) and (E-1-2) are favorable from the viewpoint of the etching resistance of the resist film obtained.

The (n+1)-valent group E represented by Formula (E-2) above is, for example, a group represented by the following Formulae (E-2-1) to (E-2-6).

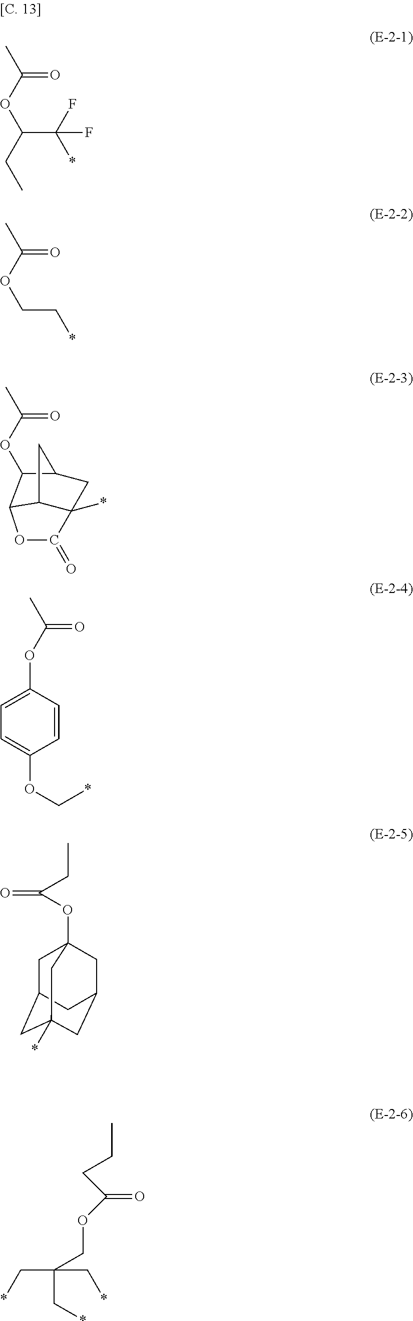

In Formulae (E-2-1) to (E-2-6) above, * is the same as that in Formula (E-2).

Among the groups represented by Formulae (E-2-1) to (E-2-6), the groups respectively represented by Formulae (E-2-1) to (E-2-4) are favorable, for facile dissociation of the alkali-dissociable group of the structural unit (A2-i) represented by Formula (2).

Examples of the monovalent linear hydrocarbon groups represented by Rf above in Formula (2) include methyl, ethyl, propyl, butyl, pentyl, hexyl, octyl, decyl, dodecyl, hexadecyl, octadecyl, and the like.

Examples of the monovalent aromatic hydrocarbon groups represented by Rf above include aryl groups such as phenyl, tolyl, xylyl, and naphthyl and aralkyl groups such as benzyl, phenethyl, and phenylpropyl.

Examples of the substituted monovalent linear hydrocarbon groups, of which part or all of the hydrogen atoms are substituted with fluorine atom, represented by Rf above include trifluoromethyl, 2,2,2-trifluoroethyl, perfluoroethyl, 3,3,3-trifluoro-n-propyl, 2,2,3,3,3-pentafluoro-n-propyl, perfluoro-n-propyl, 1,1,1,3,3,3-hexafluoro-i-propyl, 2,2,3,3,4,4,4-heptafluoro-n-butyl, perfluoro-n-butyl, and the like.

Examples of the monovalent aromatic hydrocarbon groups, of which part or all of the hydrogen atoms are substituted with fluorine atoms, represented by Rf above include fluorophenyl, trifluorophenyl, pentafluorophenyl, trifluoromethylphenyl, di(trifluoromethyl)phenyl, tri(trifluoromethyl)phenyl, fluoronaphthyl, trifluoromethylnaphthyl, and the like.

The structural unit (A2-i) represented by Formula (2) above is preferably a structural unit represented by the following Formula (2-1) to (2-4) (hereinafter, referred to also as a “structural unit (A2-1) to (A2-4)”). When the structural unit (A2-i) is a structural unit of (A2-1) to (A2-4), it is possible to increase the content of the structural units in the block copolymer (A), as the monomer giving the structural unit is highly copolymerizable. It is thus possible to increase the post-development hydrophilicity of the surface of the resist film formed from the radiation-sensitive resin composition and thus to form a resist pattern with fewer development defects.

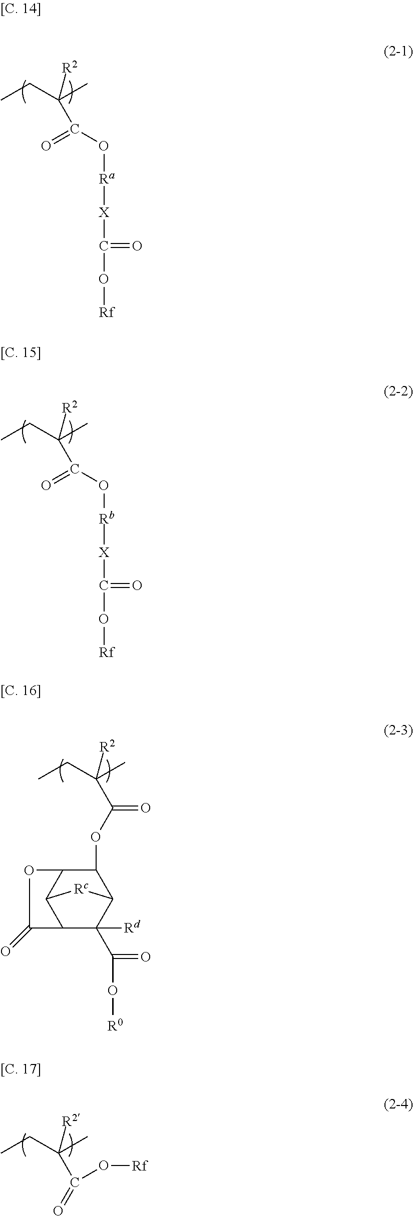

### [Structural Unit (A2-1)]

In Formula (2-1) above showing the structural unit (A2-1), R² and Rf are the same as those in Formula (2) above. Ra represents a bivalent linear hydrocarbon group or a bivalent aromatic hydrocarbon group. Part or all of the hydrogen atoms in the linear hydrocarbon group and the aromatic hydrocarbon group may be substituted. X represents a bivalent hydrocarbon group of which at least one hydrogen atom is substituted with a fluorine atom.

The bivalent linear hydrocarbon group represented by Ra above is, for example, a group similar to the bivalent linear hydrocarbon group exemplified in the description of the group E in Formula (2).

The bivalent aromatic hydrocarbon group represented by Ra above is, for example, a group similar to the bivalent aromatic hydrocarbon group exemplified in the description of the group E in Formula (2).

The bivalent hydrocarbon group, of which at least one hydrogen atom is substituted with a fluorine atom, represented by X in Formula (2-1) above is, for example, a bivalent linear hydrocarbon group having a carbon number of 1 to 20, a bivalent aliphatic cyclic hydrocarbon group having a carbon number of 3 to 20, or a bivalent aromatic hydrocarbon group having a carbon number of 6 to 20, of which part or all of the hydrogen atoms is substituted with fluorine atoms.

The bivalent linear hydrocarbon group having a carbon number of 1 to 20 is preferably a bivalent linear hydrocarbon group having a carbon number of 1 to 10 and more preferably a bivalent linear hydrocarbon group having a carbon number of 1 to 5.

The bivalent aliphatic cyclic hydrocarbon group having a carbon number of 3 to 20 is preferably a monocyclic saturated hydrocarbon group and more preferably a cyclopentandiyl or cyclohexandiyl group.

The bivalent aromatic hydrocarbon group having a carbon number of 6 to 20 is preferably a phenylene, benzylene, or phenethylene group.

With respect to the group X in Formula (2-1) above, a fluorine atom or a fluorine atom-containing carbon atom is preferably bound to the terminal carbon atom on the side binding to the carbonyl group, i.e., the carbon atom bound to COORf in Formula (2-1) and more preferably, a fluorine atom or a perfluoroalkyl group is bound to the carbon atom. When the group X has such a structure, the block copolymer (A) shows improved reactivity to the developing solution.

The group X in Formula (2-1) is, for example, a group represented by the following Formulae (X-1) to (X-6).

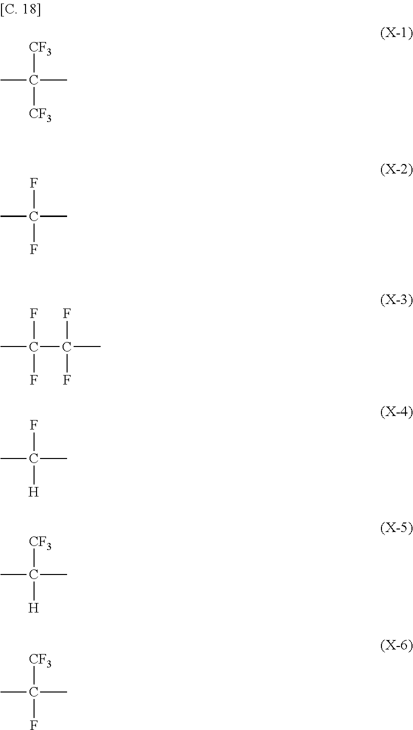

Among them, the group X is preferably a group represented by Formula (X-2) or (X-3) and more preferably a group represented by Formula (X-2).

The group Rf is preferably a monovalent aromatic hydrocarbon group which may have one or more substituents or a monovalent linear hydrocarbon group which may have one or more fluorine atoms (hereinafter, these groups will be referred to as groups “Rf³”.) The structural unit (A2-1) is preferably a structural unit (A2-1-1) represented by the following Formula (2-1-1).

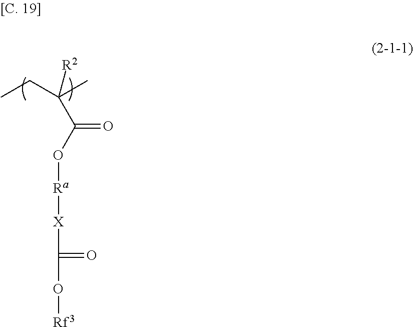

In Formula (2-1-1) above, R², Ra, and X are the same as those described in Formula (2-1). Rf³ is a monovalent aromatic hydrocarbon group which may have one or more substituents or a monovalent linear hydrocarbon group which may have one or more fluorine atoms.

Examples of the monovalent aromatic hydrocarbon groups represented by Rf³ above include aryl groups such as phenyl, naphthyl, and tolyl and aralkyl groups such as benzyl and phenethyl.

Examples of the substituent groups possibly introduced to the monovalent aromatic hydrocarbon group represented by Rf³ above include the substituent groups possibly introduced to the group E in Formula (2) and the like. In particular, the substituent group is preferably a halogen atom or R^{p1}, more preferably a fluorine atom or an alkyl group having a carbon number of 1 to 10, of which part or all of the hydrogen atoms may be substituted, and still more preferably a fluorine atom or a trifluoromethyl group. When the group Rf³ is a monovalent aromatic hydrocarbon group, it preferably has 1 to 5 substituent groups, more preferably 1 to 3 substituent groups, and still more preferably 1 to 2 substituent groups.

Examples of the monovalent linear hydrocarbon group represented by Rf³ above include methyl, ethyl, propyl, butyl, pentyl, and the like. Among them, methyl and ethyl groups are preferable.

The fluorine atom-containing monovalent linear hydrocarbon group represented by Rf³ above is for example a monovalent linear hydrocarbon group described above, of which at least one hydrogen atom is substituted with a fluorine atom. Among the groups above, trifluoromethyl, 2,2,2-trifluoroethyl, perfluoroethyl, 2,2,3,3,3-pentafluoropropyl, 1,1,1,3,3,3-hexafluoropropyl, perfluoro-n-propyl, perfluoro-i-propyl, perfluoro-n-butyl, perfluoro-i-butyl, perfluoro-t-butyl, 2,2,3,3,4,4,5,5-octafluoropentyl, and perfluorohexyl groups are preferable.

The group represented by Rf³ above is preferably a group represented by the following Formulae (Rf³-a) to (Rf³-f) and more preferably a group represented by the following Formulae (Rf³-a) to (Rf³-c).

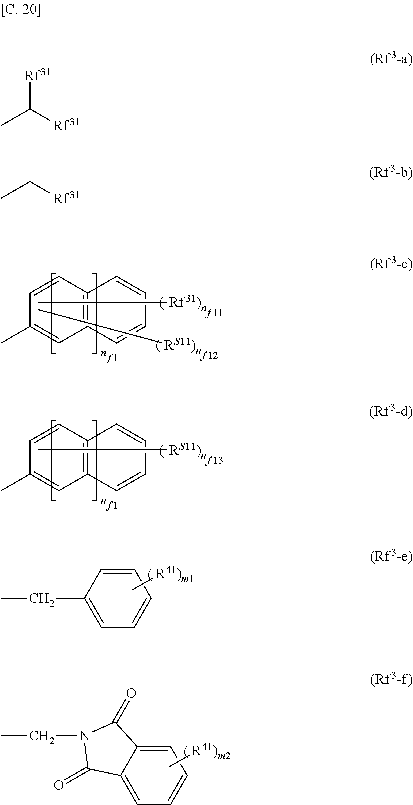

In Formulae (Rf³-a) to (Rf³-c) above, multiple groups Rf³¹ each independently represent a monovalent linear hydrocarbon group which may have one or more fluorine atoms. R^{S11} each independently represent a substituent group. n_{f1} each independently is 0 or 1. n_{f11} is an integer of 1 to (5+2n_{f1}). n_{f12} is an integer of 0 to (5+2n_{f1}). However, they satisfy the condition of n_{f11}+n_{f12}≦5+2n_{f1}. n_{f13} is an integer of 0 to (5+2n_{f1}).

In Formulae (Rf³-e) and (Rf³-f) above, multiple groups R⁴¹ each independently represent a substituent group. m1 is an integer of 0 to 5. m2 is an integer of 0 to 4.

The monovalent linear hydrocarbon group which may have one or more fluorine atoms represented by Rf³¹ above is, for example, a group similar to the monovalent linear hydrocarbon group which may have one or more fluorine atoms exemplified above as Rf³. Among the groups above, methyl, ethyl, trifluoromethyl, 2,2,2-trifluoroethyl, perfluoroethyl, 2,2,3,3,3-pentafluoropropyl, 1,1,1,3,3,3-hexafluoropropyl, perfluoro-n-propyl, perfluoro-i-propyl, perfluoro-n-butyl, perfluoro-i-butyl, perfluoro-t-butyl, 2,2,3,3,4,4,5,5-octafluoropentyl, and perfluorohexyl groups are preferable, and methyl and ethyl groups are more preferable.

Examples of the substituent groups represented by R^{S11} above include —R^{S1′}, —R^{S2′}—O—R^{S1′}, —R^{S2′}—CO—R^{S1′}, —R^{S2′}—CO—OR^{S1′}, —R^{S2′}—O—CO—R^{S1′}, —R^{S2′}—CN, and the like.

The group R^{S1′} above is an alkyl group having a carbon number of 1 to 10, a cycloalkyl group having a carbon number of 3 to 20, or an aryl group having a carbon number of 6 to 30. The group R^{S2′} above is a single bond, an alkanediyl group having a carbon number of 1 to 10, a cycloalkanediyl group having a carbon number of 3 to 20, or an arylene group having a carbon number of 6 to 30.

Among them, it is preferably —R^{S1′}, —R^{S2′}—O—R^{S1′}, —R^{S2′}—CO—R^{S1′}, —R^{S2′}—CO—OR^{S1′}, or —R^{S2′}—O—CO—R^{S1′} and more preferably —R^{S1′}.

Examples of the substituent groups represented by R⁴¹ in Formulae (Rf³-e) and (Rf³-f) above include —R^{Q1}, —R^{Q2}—O—R^{Q1}, —R^{Q2}—CO—R^{Q1}, —R^{Q2}—CO—OR^{Q1}, —R^{Q2}—O—CO—R^{Q1}, —R^{Q2}—OH, —R^{Q2}—CN, —R^{Q2}—COOH, and the like.

The group R^{Q1} above is a monovalent linear saturated hydrocarbon group having a carbon number of 1 to 10, a monovalent aliphatic cyclic saturated hydrocarbon group having a carbon number of 3 to 20, or a monovalent aromatic hydrocarbon group having a carbon number of 6 to 30. The group R^{Q2} is a single bond, a bivalent linear saturated hydrocarbon group having a carbon number of 1 to 10, a bivalent aliphatic cyclic saturated hydrocarbon group having a carbon number of 3 to 20, or a bivalent aromatic hydrocarbon group having a carbon number of 6 to 30. Here, part or all of the hydrogen atoms in R^{Q1} and R^{Q2} above may be substituted with fluorine atoms.

More specifically, the structural unit (A2-1) represented by Formula (2-1) is preferably a structural unit represented by the following Formulae (2-1a) to (2-1e). When the structural unit (A2-1) is one of the particular structural units, because it has electron-withdrawing property, the hydrolytic reaction rate during alkali development increases significantly and the resist film shows higher surface hydrophilicity after alkali development, consequently giving a resist pattern with fewer development defects.

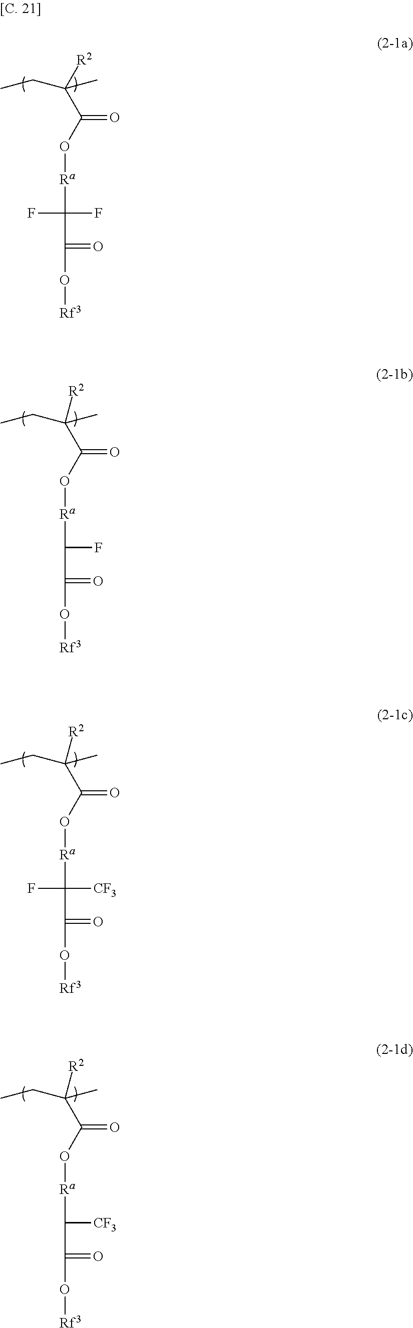

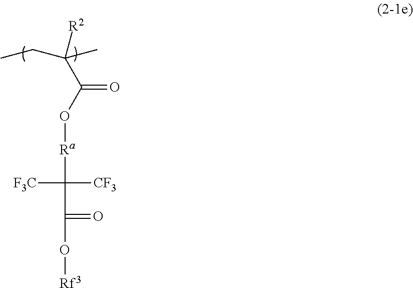

R², R^{a}, and Rf³ in Formulae (2-1a) to (2-1e) are the same as those described in Formula (2-1).

The structural units represented by Formulae (2-1a) to (2-1e) are, for example, the structural units represented by the following Formulae ([C. 22] and [C. 23]).

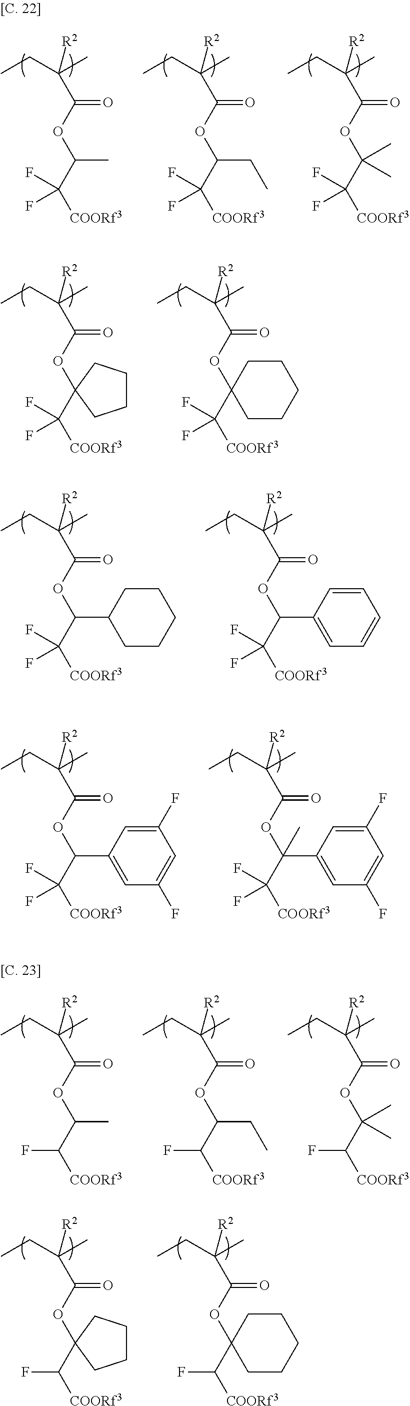

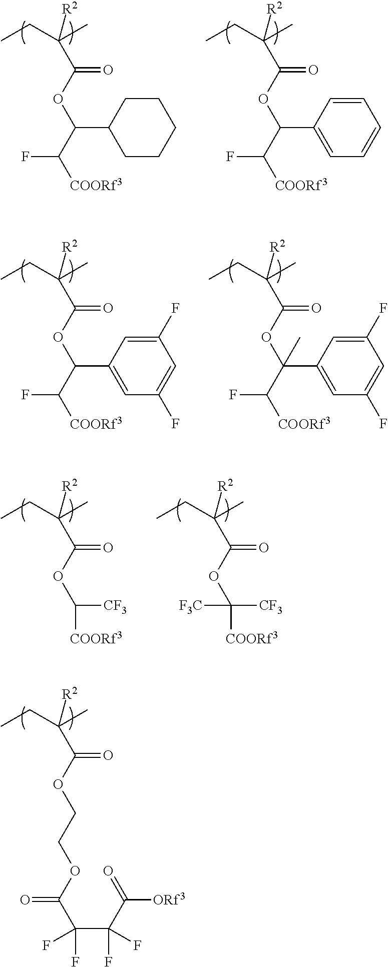

In Formulae ([C. 22] and [C. 23]) above, R² and Rf³ are the same as those in Formula (2-1-1) above.

Examples of the structural units (A2-1) include the structural units represented by the following Formula ([C. 24]) and the like.

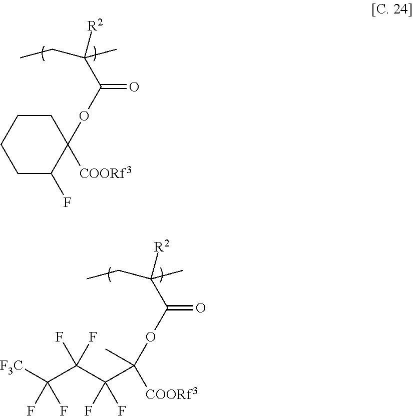

In the Formula above, R² and Rf³ are the same as those in Formula (2-1-1) above.

Among them, the structural unit (A2-1) is preferably a structural unit derived from 1,1-difluoro-2-butyl (meth)acrylate to which a COORf³ group is bound at the 1 position. The Rf³ group is preferably a monovalent linear hydrocarbon group or a monovalent aromatic hydrocarbon group, more preferably a methyl, ethyl, 2,2,2-trifluoroethyl, or trifluoromethyl-substituted phenyl group.

### [Structural Unit (A2-2)]

The structural unit (A2-2) described above is a structural unit represented by Formula (2-2).

In Formula (2-2) above, R² and Rf are the same as those in Formula (2) above.

R^{b} in Formula (2-2) represents a bivalent linear hydrocarbon group, a bivalent aliphatic cyclic hydrocarbon group, or a bivalent aromatic hydrocarbon group, and part or all of the hydrogen atoms in these hydrocarbon groups may be substituted.

The bivalent linear hydrocarbon group, the bivalent aliphatic cyclic hydrocarbon group, and the bivalent aromatic hydrocarbon group which may have one or more substituents represented by R^{b} above are, for example, groups similar to those exemplified as the bivalent group E in Formula (2) above.

The group R^{b} is preferably 1,2-ethanediyl, 2,6-norbornane-lactonediyl, or phenyleneoxymethylene.

The group Rf is preferably a fluorine atom-containing monovalent linear hydrocarbon group and more preferably a 2,2,2-trifluoroethyl, 1,1,1,3,3,3-hexafluoro-i-propyl, or 2,2,3,3,3-pentafluoro-n-propyl group.

### [Structural Unit (A2-3)]

The structural unit (A2-3) described above is a structural unit represented by Formula (2-3).

In Formula (2-3) above, R² is the same as that in Formula (2) above. R^{o} represents a monovalent aromatic hydrocarbon group. Part or all of the hydrogen atoms in the aromatic hydrocarbon group may be substituted. R^{c} represents a methylene group, —CH(CH₃)—, —C(CH₃)₂—, —CH₂CH₂—, or an oxygen atom. R^{d} represents a hydrogen atom or a monovalent organic group.

The “organic group,” as used in the present description, is a group having at least one carbon atom.

Examples of the monovalent aromatic hydrocarbon groups represented by R^{o} above include aryl groups such as phenyl, naphthyl, and tolyl; aralkyl groups such as benzyl and phenethyl; groups derived from these aryl and aralkyl groups of which part or all of the hydrogen atoms are substituted with substituent groups, and the like. Examples of the substituent groups include the substituent groups for the group E in Formula (2) and the like. Among the substituent groups above, halogen atoms and R^{p1} are preferable; a fluorine atom and monovalent linear saturated hydrocarbon groups having a carbon number of 1 to 10 of which part or all of the hydrogen atoms may be substituted are more preferably; and a fluorine atom and a trifluoromethyl group are still more preferable. The number of substituent groups of R^{o} is preferably 1 to 5, more preferably 1 to 3, and still more preferably 1 to 2.

The group R^{o} is preferably a group represented by Formula (Rf³-c) or (Rf³-d) in the structural unit (A2-1).

### [Structural Unit (A2-4)]

The structural unit (A2-4) described above is a structural unit represented by Formula (2-4) above.

In Formula (2-4) above, Rf is the same as that in Formula (2). R^{2′} represents a monovalent linear hydrocarbon group having a carbon number of 1 to 4 of which at least one hydrogen atom is substituted with a fluorine atom.

Examples of the monovalent linear hydrocarbon group of which at least one hydrogen atom is substituted with a fluorine atom represented by R^{2′} above include fluoromethyl, difluoromethyl, trifluoromethyl, fluoroethyl, difluoroethyl, trifluoroethyl, perfluoroethyl, fluoropropyl, trifluoropropyl, heptafluoropropyl, fluorobutyl, trifluorobutyl, nonafluorobutyl, and the like.

Examples of the monovalent linear hydrocarbon groups which may have one or more fluorine atoms represented by Rf above include those exemplified as Rf in Formula (2) and the like.

Examples of the monovalent aromatic hydrocarbon groups which may have one or more fluorine atoms represented by Rf above include those exemplified as Rf in Formula (2) above and the like.

### (Content of Structural Units (A2))

The content of the structural units (A2) in block copolymer (A) is preferably 50 to 95 mol %, more preferably 55 to 90 mol %, and still more preferably 60 to 85 mol %, with respect to the total structural units constituting the block copolymer (A). It is possible at such a content to make the surface of the resist more hydrophobic during liquid-immersion exposure and thus make the surface of the resist more hydrophilic after development.

Alternatively, the content of the structural units (A2) in polymer block (II) is preferably 20 to 100 mol %, more preferably 30 to 70 mol %, and still more preferably 40 to 60 mol %, with respect to the total structural units constituting the polymer block (II).

The block copolymer (A) may have another structural unit, if it has a polymer block (I) of repeating structural units (A1) and a polymer block (II) of repeating structural units (A2), as described above.

For example, the block copolymer (A) may have structural units that alter the polarity of the block copolymer (A) by addition of an alkaline developing solution or structural units increasing the solubility of the block copolymer (A) in the alkaline developing solution.

The block copolymer (A) may have the structural units (A3) and (A4) described below as the fluorine atom-providing structural units, or may have, besides these structural units (A3) and (A4), other structural units additionally. In this case, the other structural unit, besides the structural units (A3) and (A4), may be contained either in the polymer block (I) or (II) or in both of them.

### [Structural Unit (A3)]

The structural unit (A3) that may be present in the block copolymer (A) is represented by the following Formula (3).

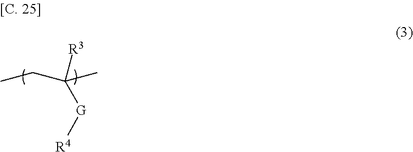

In Formula (3) above, R³ represents a hydrogen or fluorine atom or a monovalent linear hydrocarbon group having a carbon number of 1 to 4. Part or all of the hydrogen atoms in the linear hydrocarbon group may be substituted with halogen atoms.

In Formula (3) above, G represents a single bond, an oxygen or sulfur atom, —CO—O—, —SO₂—O—NH—, —CO—NH—, or —O—CO—NH—.

In Formula (3) above, R⁴ represents a monovalent linear hydrocarbon group having a carbon number of 1 to 6 containing at least one fluorine atom or a monovalent aliphatic cyclic hydrocarbon group having a carbon number of 4 to 20 containing at least one fluorine atom.

The monovalent linear hydrocarbon group represented by R³ above is, for example, a group similar to those exemplified as R² in Formula (2).

Examples of the linear hydrocarbon groups containing at least one fluorine atom represented by R⁴ above include trifluoromethyl, 2,2,2-trifluoroethyl, perfluoroethyl, 2,2,3,3,3-pentafluoro-n-propyl, 1,1,1,3,3,3-hexafluoro-i-propyl, perfluoro-n-propyl, perfluoro-i-propyl, perfluoro-n-butyl, perfluoro-i-butyl, perfluoro-t-butyl, 2,2,3,3,4,4,5,5-octafluoropentyl, perfluorohexyl, and the like.

Examples of the aliphatic cyclic hydrocarbon groups containing at least one fluorine atom represented by R⁴ above include monofluorocyclopentyl, difluorocyclopentyl, perfluorocyclopentyl, monofluorocyclohexyl, difluorocyclopentyl, perfluorocyclohexylmethyl, fluoronorbornyl, fluoroadamantyl, fluorobornyl, fluoroisobornyl, fluorotricyclodecyl, fluorotetracyclodecyl, and the like.

Examples of the monomers giving the structural units (A3) include trifluoromethyl (meth)acrylic ester, 2,2,2-trifluoroethyl (meth)acrylic ester, perfluoroethyl (meth)acrylic ester, perfluoro-n-propyl (meth)acrylic ester, perfluoro-i-propyl (meth)acrylic ester, perfluoro-n-butyl (meth)acrylic ester, perfluoro-i-butyl (meth)acrylic ester, perfluoro-t-butyl (meth)acrylic ester, 2-(1,1,1,3,3,3-hexafluoropropyl) (meth)acrylic ester, 1-(2,2,3,3,4,4,5,5-octafluoropentyl) (meth)acrylic ester, perfluorocyclohexylmethyl (meth)acrylic ester, 1-(2,2,3,3,3-pentafluoropropyl) (meth)acrylic ester, monofluorocyclopentyl (meth)acrylic ester, difluorocyclopentyl (meth)acrylic ester, perfluorocyclopentyl (meth)acrylic ester, mono fluorocyclohexyl (meth)acrylic ester, difluorocyclopentyl (meth)acrylic ester, perfluorocyclohexylmethyl (meth)acrylic ester, fluoronorbornyl (meth)acrylic ester, fluoroadamantyl (meth)acrylic ester, fluorobornyl (meth)acrylic ester, fluoroisobornyl (meth)acrylic ester, fluorotricyclodecyl (meth)acrylic ester, and fluorotetracyclodecyl (meth)acrylic ester, and the like.

### (Content of Structural Units (A3))

The content of the structural units (A3) in block copolymer (A) is preferably 5 to 40 mol % and more preferably 10 to 20 mol %, with respect to the total structural units constituting the block copolymer (A). It is possible at such a content to make the surface of the resist film more hydrophobic during liquid-immersion exposure.

When the structural unit (A3) is contained in the polymer block (II), the content of the structural units (A3) in polymer block (II) is preferably 50 to 100 mol %, more preferably 70 to 100 mol %, and still more preferably 80 to 100 mol %, with respect to the total structural units constituting the polymer block (II).

### [Structural Unit (A4)]

The structural unit (A4) that may be contained in the block copolymer (A) is represented by the following Formula (4).

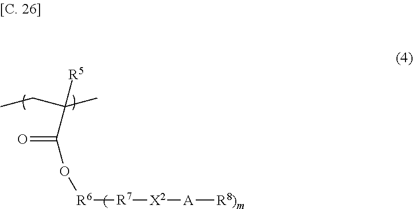

In Formula (4) above, R⁵ represents a hydrogen or fluorine atom or a monovalent linear hydrocarbon group having a carbon number of 1 to 4 and the monovalent linear hydrocarbon group having a carbon number of 1 to 4 may have at least one halogen atom.

In Formula (4) above, R⁶ represents a (m+1)-valent hydrocarbon group having a carbon number of 1 to 20 and examples thereof include the structures having an oxygen or sulfur atom, —NR′—, a carbonyl group, —CO—O—, or —CO—NH— bound to the R⁷-sided terminal of R⁶. R′ represents a hydrogen atom or a monovalent organic group.

In Formula (4) above, R⁷ represents a single bond, a bivalent linear hydrocarbon group having a carbon number of 1 to 10, or a bivalent aliphatic cyclic hydrocarbon group having a carbon number of 4 to 20.

In Formula (4) above, X² represents a single bond or a bivalent linear hydrocarbon group having a carbon number of 1 to 20 containing at least one fluorine atom.

In Formula (4) above, A represents an oxygen atom, —NR″—, —CO—O—*, or —SO₂—O—*. R″ represents a hydrogen atom or a monovalent organic group. * indicates the position to which R⁸ binds.

In Formula (4) above, R⁸ represents a hydrogen atom or a non-alkali-dissociable monovalent organic group. m is an integer of 1 to 3. When m is 2 or 3, the multiple groups R⁷, X², A, and R⁸ may be the same as or different from each other.

R⁸ above is preferably a hydrogen atom, as it is possible to improve the solubility of the block copolymer (A) in the alkaline developing solution.

The monovalent organic group represented by R⁸ above is, for example, an acid-dissociable group having a carbon number of 3 to 20 and the like.

When R⁸ is an acid-dissociable group, the structural unit (A4) gives a polar group under the action of an acid. Thus, the group R⁸ is preferably an acid-dissociable group, as it is possible to increase the solubility of the region photoirradiated in the liquid-immersion exposure step of the resist-patterning method described below.

Examples of the acid-dissociable groups represented by R⁸ above include t-butoxycarbonyl, tetrahydropyranyl, tetrahydrofuranyl, (thiotetrahydropyranylsulfanyl)methyl, (thio tetrahydrofuranylsulfanyl)methyl, alkoxy-substituted methyls, alkylsulfanyl-substituted methyls, and the like.

The alkoxy group (substituent group) of the alkoxy-substituted methyl groups is, for example an alkoxy group having a carbon number of 1 to 4. The alkyl group (substituent group) of the alkylsulfanyl-substituted methyl group is, for example, an alkyl group having a carbon number of 1 to 4.

The acid-dissociable group is, for example, a group represented by Formula (Y-1) as described in the description of structural unit (A1-1) above. Among the groups above, when A in Formula (4) is an oxygen atom or —NR″—, it is preferably a t-butoxycarbonyl group or an alkoxy-substituted methyl group. Alternatively when A in Formula (4) is —CO—O—, it is preferably a group represented by Formula (Y-1) group, as exemplified in the description of the structural unit (A1-1) of polymer block (I).

The bivalent linear hydrocarbon group containing at least one fluorine atom represented by X² above is, for example, a group represented by Formula (X-1) to (X-6), which was described as examples of X in Formula (2-1) above.

When A above is an oxygen atom, the group X² is preferably a group represented by Formula (X-1). Alternatively when A is —CO—O—, it is preferably a group represented by Formulae (X-2) to (X-6) and more preferably a group represented by Formula (X-3).

The structural unit (A4) is, for example, a structural unit represented by the following Formulae (4-1a) to (4-1c).

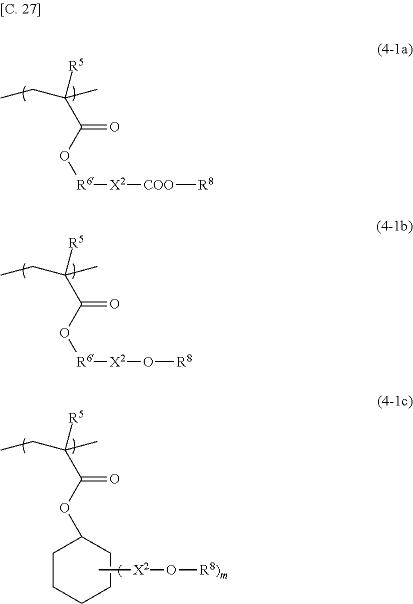

In Formulae (4-1a) to (4-1c) above, R^{6′} is a bivalent linear, branched, or cyclic saturated or unsaturated hydrocarbon group having a carbon number of 1 to 20. R⁵, X², R⁸, and m are the same as those in Formula (4).

Examples of the monomers giving the structural unit (A4) include the compounds represented by the following Formulae (4m-1) to (4m-5) and the like.

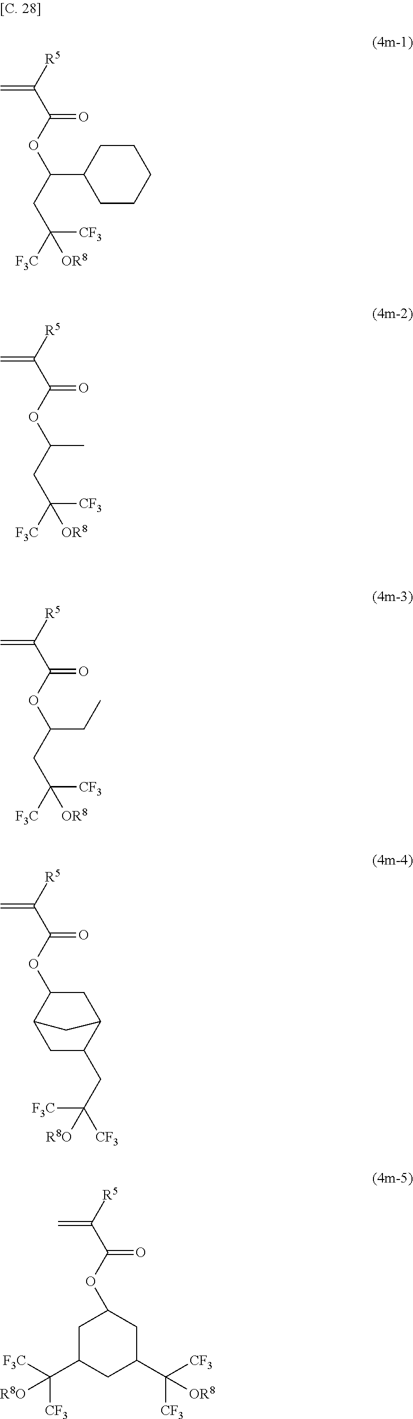

In Formulae (4m-1) to (4m-5) above, R⁵ and R⁸ are the same as those in Formula (4).

### (Content of Structural Unit (A4))

The content of the structural units (A4) in the block copolymer (A) is preferably 2.5 to 20 mol % and more preferably 3.5 to 15 mol %, with respect to the total structural units constituting the block copolymer (A). It is possible at such a content to make the surface of the resist film formed from the radiation-sensitive resin composition more hydrophilic after alkali development.

If the structural units (A4) are contained in the polymer block (II), the content of the structural units (A4) in the polymer block (II) is preferably 5 to 20 mol %, more preferably 5 to 15 mol %, and still more preferably 5 to 10 mol %, with respect to the total structural units constituting the polymer block (II).

### [Other Structural Units]

The block copolymer (A) may have, besides the arbitrary structural units (A3) and (A4) described above, other structural units such as structural units having an alkali-solubility-providing group (hereinafter, referred to also as “structural unit (A5)”), and structural units (A6) having a lactone-containing group or a cyclic carbonate-containing group as will be described in the polymer (C) below.

The block copolymer (A), when it contains a structural unit (A5) or (A6), shows improved affinity to the developing solution.

In the structural unit (A5), the alkali-solubility-providing group providing the structural unit (A5) with alkali-solubility action is preferably a functional group containing a hydrogen atom having an acid dissociation constant pKa of 4 to 11. The block copolymer (A) containing such structural units (A5) having a functional group would be likely to improve the solubility of the resist film formed from the radiation-sensitive resin composition in the alkaline developing solution. Examples of the functional groups include functional groups represented by the following Formulae (5s-1) and (5s-2) and the like.

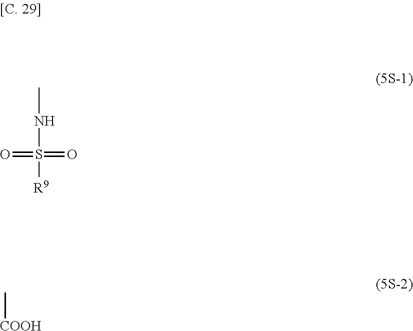

In Formula (5s-1) above, R⁹ represents a hydrocarbon group having a carbon number of 1 to 10 containing at least one fluorine atom.

The hydrocarbon group containing at least one fluorine atom represented by R⁹ above is preferably a trifluoromethyl group.

Examples of the structural units (A5) include structural units derived from (meth)acrylic acid, structural units described in WO 2009/041270, paragraphs [0018] to [0024], and the like.

The carboxy group-containing structural unit in structural unit (A5) is preferably a structural unit derived from 6-carboxy-2-norbornane-lactonyl (meth)acrylate or a structural unit derived from 2-carboxyethyl (meth)acrylate.

The structural unit (A6) is, for example, a structural unit similar to that exemplified in the description of the structural unit (A2) described above. Among such structural units, a structural unit containing a norbornane lactone-containing group is preferable, and a structural unit derived from 6-butyrolactonyloxycarbonylnorbornane-lactonyl (meth)acrylate is more preferable.

### (Content of Other Structural Units)

The content of the “other structural units,” such as the structural units (A5) and (A6), in the block copolymer (A) is normally 10 mol % or less, preferably 2 to 8 mol %, and more preferably 3 to 5 mol %, with respect to the total structural units constituting the block copolymer (A). It is possible at such a content to assure water repellency during liquid-immersion exposure and to improve the affinity to the developing solution during development simultaneously in a well-balanced manner.

When the “other structural units” are contained in the polymer block (II), the content of the “other structural units” in the polymer block (II) is preferably 5 to 20 mol %, more preferably 5 to 15 mol %, and still more preferably 5 to 10 mol %, with respect to the total structural units constituting the polymer block (II).

### (Synthetic Method for Block Copolymer (A))

The block copolymer (A) can be prepared, for example, by polymerizing the monomer constituting one polymer block (one of polymer blocks (I) and (II)) and, after completion of the polymerization reaction, adding and polymerizing the monomer constituting the other polymer block (one of polymer blocks (I) and (II)). The completion of polymerization reaction can be determined, for example, by analyzing the polymerization solution by gas chromatography.

The polymerization method for the block copolymer (A) is not particularly limited, and it can be prepared by a polymerization method such as anionic or radical polymerization. The polymerization reaction preferably proceeds by living polymerization.

The polymerization method for block copolymer (A) is preferably, for example, living anionic or radical polymerization, and reversible addition-fragmentation chain transfer (RAFT) polymerization is preferable as the living radical polymerization.

An anionic polymerization initiator is used when the block copolymer (A) is synthesized by anionic polymerization. Examples thereof include alkyl lithiums such as n-butyl lithium, sec-butyl lithium, and t-butyl lithium; alkylene dilithiums such as 1,4-dilithiobutane; phenyl lithium, stilbene lithium, lithium naphthalene, sodium naphthalene, potassium naphthalene, n-butylmagnesium, n-hexylmagnesium, ethoxycalcium, calcium stearate, t-butoxystrontium, ethoxybarium, isopropoxybarium, ethylmercaptobarium, t-butoxybarium, phenoxybarium, diethylaminobarium, barium stearate, and the like.

A radical polymerization initiator is used when the block copolymer (A) is synthesized by radical polymerization. Examples thereof include azo-based radical polymerization initiators, peroxide-based radical polymerization initiators, and the like.

Typical examples of the azo-based radical polymerization initiators include azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), dimethyl 2,2′-azobis(isobutyrate), and the like.

Typical examples of the peroxide-based radical polymerization initiators include benzoyl peroxide, t-butyl hydroperoxide, cumene hydroperoxide, and the like.

Among the compounds above, azo-based radical polymerization initiators are preferable, AIBN and dimethyl 2,2′-azobis(isobutyrate) are more preferable, and AIBN is still more preferable. These radical initiators may be used alone or as a mixture of two or more.

Examples of the chain-transfer agent, which are used in RAFT polymerization for synthesis of the block copolymer (A), include thiocarbonylthio compounds such as dithioesters, dithiocarbamates, trithiocarbonates, and xanthate.

Typical examples of the chain-transfer agents include bis(n-octylmercapto-thiocarbonyl)disulfide, 4-cyano-4-[(dodecyl sulfanylthiocarbonyl)sulfanyl]pentanoic acid, 2-(dodecylthiocarbonothioylthio)-2-methylpropionic acid, 2-cyano-2-propyldodecyl trithiocarbonate, 4-cyano-4-(phenylcarbonothioylthio)pentanoic acid, cyanomethyldodecyl trithiocarbonate, 2-cyano-2-propylbenzodithionate, and the like.

Examples of the solvents used in polymerization for the block copolymer (A) include alkanes, cycloalkanes, aromatic hydrocarbons, halogenated hydrocarbons, saturated carboxylic acid esters, ketones, ethers, alcohols, and the like.

Typical examples of the alkanes include n-pentane, n-hexane, n-heptane, n-octane, n-nonane, n-decane, and the like.

Typical examples of the cycloalkanes include cyclohexane, cycloheptane, cyclooctane, decaline, norbornane, and the like.

Typical examples of the aromatic hydrocarbons include benzene, toluene, xylene, ethylbenzene, cumene, and the like.

Typical examples of the halogenated hydrocarbons include chlorobutanes, bromohexanes, dichloroethanes, hexamethylene dibromides, chlorobenzene, and the like.

Typical examples of saturated carboxylic acid esters include ethyl acetate, n-butyl acetate, i-butyl acetate, methyl propionate, and the like.

Typical examples of the ketones include acetone, 2-butanone, 4-methyl-2-pentanone, 2-heptanone, and the like.

Typical examples of the ethers include tetrahydrofuran, dimethoxyethanes, diethoxyethanes, and the like.

Typical examples of the alcohols include methanol, ethanol, 1-propanol, 2-propanol, 4-methyl-2-pentanol, and the like.

The solvents can be used alone or in combination of two or more.

The reaction temperature of polymerization for the block copolymer (A) is normally 40° C. to 150° C. and preferably 50° C. to 120° C. The reaction period is normally 1 hour to 48 hours and preferably 1 hour to 24 hours.

The Mw of the block copolymer (A) is preferably 1000 or more and 30000 or less. When the Mw of the block copolymer (A) is within the particular range above, it is possible to obtain easily a radiation-sensitive resin composition that gives a resist pattern having a favorable pattern shape with fewer development defects.

The smallest Mw of the block copolymer (A) is preferably 1000, more preferably 2000, and still more preferably 2500. Alternatively, the largest Mw of the block copolymer (A) is preferably 30000, more preferably 25000, and still more preferably 20000.

The ratio (Mw/Mn) of the Mw of the block copolymer (A) to the number-average molecular weight (Mn) thereof as polystyrene is preferably 1.0 to 2.5 and more preferably 1.0 to 2.0.

In the present description, the Mw of polymer is a value determined by gel-permeation chromatography (GPC) under the following condition.

### (GPC Measurement Condition)

GPC column: two G2000HXL columns, one G3000HXL column, and one G4000HXL column, respectively produced by Tosoh Corporation

Column temperature: 40° C.

Elution solvent: tetrahydrofuran (produced by Wako Pure Chemical Industries)

Flow rate: 1.0 mL/minute

Sample concentration: 1.0 mass %

Sample injection volume: 100 μL

Detector: differential refractometer

Standard substance: monodisperse polystyrene

More specific favorable examples of the synthetic methods for the block copolymer (A) include the synthetic methods described in Examples below and the following synthetic method.

The monomer constituting the polymer block (I) above is dissolved in a “solvent used for polymerization of the block copolymer (A)” described above, a chain-transfer agent is added thereto, and the mixture is heated at a temperature in the range above for a period in the range above.

A liquid mixture containing a polymerization initiator and a solvent is added thereto over a particular period (for example, 3 to 12 hours).

Then, a mixture solution containing the monomer constituting the polymer block (II), a polymerization initiator, and a solvent is added over a particular period (for example, 3 to 12 hours). After polymerization, the polymerization solution is cooled, for example, to 30° C. or lower, added to a solvent, permitting precipitation of the solid matter. After-treatment of the solid matter, for example by decantation, washing, and concentration, gives the block copolymer (A).

### (Content of Block Copolymer (A))

The content of the block copolymer (A) in the radiation-sensitive resin composition according to the present invention is not particularly limited.

For example, the content of the block copolymer (A) may be used as the major component, as it is contained in an amount of 50 mass % or more with respect to the total solid matter in the radiation-sensitive resin composition. When the block copolymer (A) is used as the major component with respect to the total solid of the radiation-sensitive resin composition, the content of the block copolymer (A) may be, for example, 50 mass % or more and less than 100 mass % with respect to the total solid matter.

The block copolymer (A) is preferably used in combination with an acid-dissociable group-containing polymer (C) described below. When a polymer other than the block copolymer (A) such as the polymer (C) described below is used as the major component in the total solid of the radiation-sensitive resin composition, the block copolymer (A) may be used as additive. When the block copolymer (A) is used as additive, the content of the block copolymer (A) is preferably 1 to 50 mass %, more preferably 1 to 30 mass %, and still more preferably 1 to 15 mass %, with respect to the total solid matter in the radiation-sensitive resin composition. When the block copolymer (A) is used in combination with a polymer (C), the content of the block copolymer (A) is preferably 1 to 20 parts by mass, more preferably 1 to 15 parts by mass, and still more preferably 1 to 10 parts by mass, with respect to 100 parts by mass of the polymer (C). When the content of the block copolymer (A) is in the range above, it is possible to obtain easily a radiation-sensitive resin composition that gives a resist pattern having a favorable pattern shape with fewer development defects.

### <Acid-Generating Agent (B)>

The radiation-sensitive resin composition contains an acid-generating agent (B) that generates an acid by photoirradiation. In the presence of the acid generated from the acid-generating agent (B), the acid-dissociable groups in the block copolymer (A) described above and the polymer (C) described below in the exposed region dissociate, generating polar groups such as carboxy groups and thus making these polymers soluble in the developing solution. The acid-generating agent (B) may be contained in the radiation-sensitive resin composition in the shape of a low-molecular weight compound as described below (hereinafter, referred to also as “acid generator (B)”), in the shape as it is incorporated into the block copolymer (A) or the polymer (C) as an acid generation group, or in the shape in combination thereof.

Examples of the acid generators (B) include onium salt compounds, n-sulfonyloxyimide compounds, halogen-containing compounds, diazo ketone compounds, and the like.

Examples of the onium salt compounds include sulfonium salts, tetrahydrothiophenium salts, iodonium salts, phosphonium salts, diazonium salts, pyridinium, salts and the like.

Typical examples of these acid generators (B) include the compounds described in JP-A No. 2013-68914, paragraphs [0199] to [0202], and the like.

Among the acid generators (B) above, onium salt compounds are preferable; sulfonium salts are more preferable; and 4-cyclohexylphenyldiphenylsulfonium nonafluoro-n-butanesulfonate, triphenylsulfonium adamantyl-1,1,2,2-tetrafluoroethanesulfonate, triphenylsulfonium bicyclo[2.2.1]hept-2-yl-1,1,2,2-tetrafluoroethane sulfonate, and nonafluorobutanesulfonate are still more preferable.

The acid-generating agents (B) may be used alone or in combination of two or more.

### (Content of Acid-Generating Agent (B))

When the acid-generating agent (B) is an acid generator (B), the content of the acid-generating agent (B) in the radiation-sensitive resin composition is preferably 0.1 to 20 mass % with respect to the total solid matter in the composition, to assure favorable sensitivity and printing efficiency of the radiation-sensitive resin composition. When the composition contains a polymer (C), the content of the acid-generating agent (B) is preferably 0.1 to 30 parts by mass and more preferably 0.1 to 20 parts by mass with respect to 100 parts by mass of the polymer (C). When the content of the acid-generating agent (B) is in the range above, it is possible to improve sensitivity and printing efficiency easily, yet prevent decrease in transparency to the exposure beam, and give a rectangular resist pattern easily.

### <Acid-Dissociable Group-Containing Polymer (C)>

The acid-dissociable group-containing polymer (C) is a polymer having a structural unit (C1) containing an acid-dissociable group. However, polymers corresponding to the block copolymer (A) described above are not included in these polymers (C). The polymer (C) is used favorably as the major component, as it is contained in an amount of 50 mass % or more with respect to the all polymers forming the resist pattern in the radiation-sensitive resin composition according to the embodiment of the present invention.

The polymer (C) for use is preferably a polymer that is alkali insoluble or scarcely soluble before action of an acid, as the acid-dissociable group has a role of a protecting group, and becomes alkali soluble when the acid-dissociable group (protecting group) dissociates by action of the acid. Such a polymer (C) generates a distinct difference in the solubility in the alkaline developing solution (solubilization contrast) between photoirradiated region (exposed region) and non-photoirradiated region (non-exposed region) and thus contributes to preparation of a favorable resist pattern.

The phrase “alkali insoluble or scarcely soluble” means that, when a film made only of polymer (C) having a film thickness of 100 nm is developed, replacing a resist film, under the alkali development condition used when a resist pattern is formed from a resist film prepared using a radiation-sensitive resin composition containing the polymer (C), 50% or more of the initial film thickness of the film is retained after development. Such polymers (C) may be used alone or in combination of two or more in the radiation-sensitive resin composition according to the embodiment of the present invention.

Examples of the acid-dissociable group-containing polymers (C) include “polymers containing alicyclic skeletons such as norbornane rings in the main chain” obtained by polymerization for example of a norbornene derivative, “polymers containing norbornane rings and maleic anhydride derivatives in the main chain” obtained by copolymerization of an norbornene derivative and maleic anhydride, “polymers containing norbornane rings and (meth)acrylate-derived skeletons in the main chain” obtained by copolymerization of a norbornene derivative and a (meth)acrylate compound, “polymers containing norbornane rings, maleic anhydride derivatives and (meth)acrylate-derived skeletons in the main chain” obtained by copolymerization of a norbornene derivative, maleic anhydride and a (meth)acrylate compound, “polymers containing (meth)acrylate-derived skeletons in the main chain” obtained by polymerization of a (meth)acrylate compound, and the like. Among them, the polymer (C) is preferably a “polymers containing (meth)acrylate-derived skeletons,” and more preferably a “polymer containing (meth)acrylate-derived skeletons in the main chain.”

In the present description, the term “(meth)acrylate” is a word indicating both acrylate and methacrylate.

The polymer (C) may contain, in addition to the structural units (C1) containing an acid-dissociable group, structural units (C2) containing a lactone-containing group or a cyclic carbonate-containing group, or structural units (C3) containing a polar group. Hereinafter, the structural units contained in polymer (C) will be described.

### [Structural Unit (C1)]

The structural unit containing an acid-dissociable group (C1) is a group similar to the “structural unit (A1)” in the block copolymer (A) described above and duplicated description thereof is omitted.

The structural unit (C1) in the polymer (C) is preferably a structural unit represented by Formula (1-1) or (1-2), because the acid-dissociable group therein dissociate more readily and the resist pattern obtained from the radiation-sensitive resin composition has a more favorable pattern shape. Similarly, it is more preferably a structural unit derived from 1-alkyl-substituted-1-cyclopentyl (meth)acrylate or a structural unit derived from 2-alkyl-substituted-2-adamantyl (meth)acrylate. It is most preferably a structural unit derived from 1-methyl-1-cyclopentyl (meth)acrylate, a structural unit derived from 1-ethyl-1-cyclopentyl (meth)acrylate, a structural unit derived from 2-ethyl-2-adamantyl (meth)acrylate, or a structural unit derived from 2-isopropyl-2-adamantyl (meth)acrylate.

The content of the structural unit (C1) in polymer (C) is preferably 20 mol % to 80 mol %, more preferably 30 mol % to 70 mol %, and still more preferably 40 mol % to 60 mol % with respect to the total structural units constituting the polymer (C). When the content of the structural unit (C1) is in the range above, the resist pattern formed from the radiation-sensitive resin composition has more favorable pattern shape.

### [Structural Unit (C2)]

The acid-dissociable group-containing polymer (C) preferably contains, in addition to the structural units (C1) described above, structural units (C2) containing a lactone-containing group or a cyclic carbonate-containing group.

The structural units (C2) may be used alone or in combination of two or more in the polymer (C).

The polymer (C), if it contains structural units (C2) containing a lactone-containing group or a cyclic carbonate-containing group, contributes to improvement of the adhesiveness of the resist film prepared from the radiation-sensitive resin composition to the substrate.

The lactone-containing group is a cyclic group having a ring containing a —O—C(O)— structure (lactone ring). Alternatively, the cyclic carbonate-containing group is a cyclic group containing a bond represented by —O—C(O)—O— (cyclic carbonate ring). When the lactone ring or the cyclic carbonate ring is counted as a ring, a group having only a lactone ring or a cyclic carbonate ring is referred to a monocyclic group, while a group having another ring structure additionally is referred to a polycyclic group independently of its structure.

Examples of the structural units (C2) include those represented by the following Formulae ([C. 30] and [C. 31]) and the like.

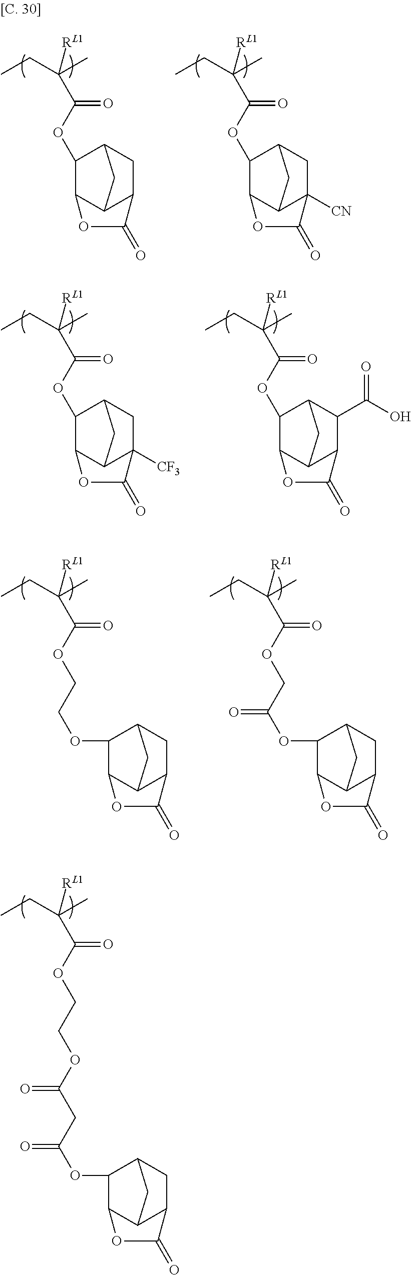

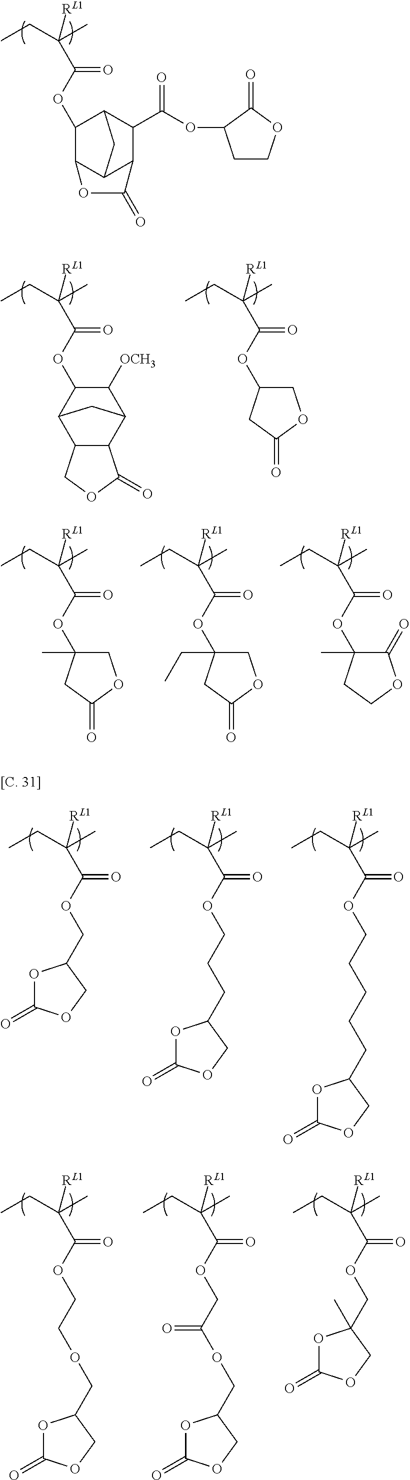

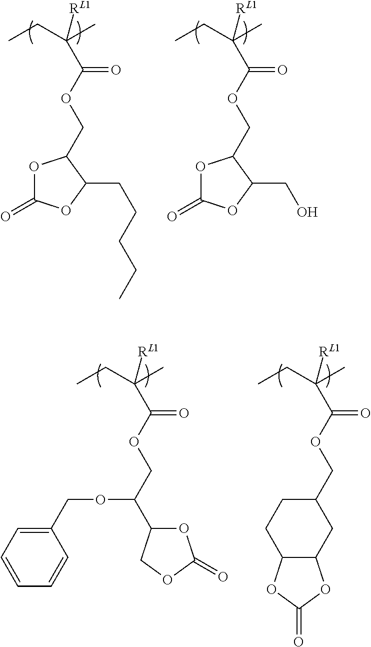

In Formulae (([C. 30] and [C. 31]) above, R^{L1} represents a hydrogen or fluorine atom or a methyl or trifluoromethyl group.

Among them, the structural unit (C2) is preferably a structural unit derived from norbornane lactonyl (meth)acrylate.

Monomers giving the structural unit (C2) are, for example, those represented by the following Formula (L-1).

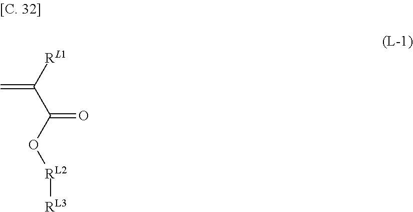

In Formula (L-1) above, R^{L1} represents a hydrogen or fluorine atom or a methyl or trifluoromethyl group. R^{L2} represents a single bond or a bivalent group. R^{L3} represents a lactone-containing group or a cyclic carbonate-containing group.

The bivalent group represented by R^{L2} above is, for example, a bivalent straight-chain or a branched hydrocarbon group having a carbon number of 1 to 20.

The lactone-containing group represented by R^{L3} above is, for example, a group represented by the following Formulae (L3-1) to (L3-6). The cyclic carbonate-containing group represented by R^{L3} above is, for example, a group represented by (L3-7) or (L3-8).

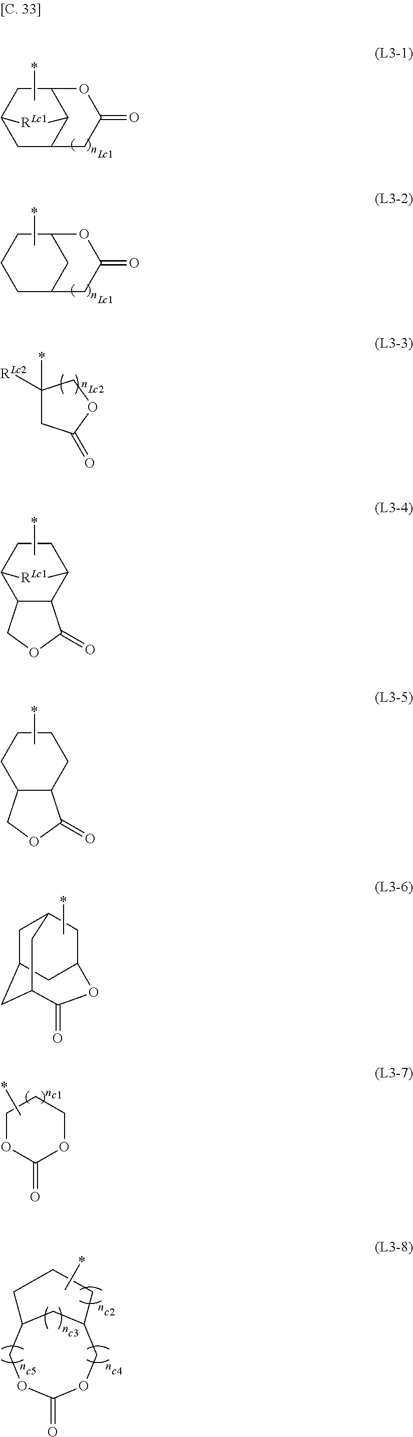

In Formulae (L3-1) and (L3-4) above, R^{Lc1} represents an oxygen atom or a methylene group.

In Formula (L3-3) above, R^{Lc2} represents a hydrogen atom or an alkyl group having a carbon number of 1 to 4.

In Formulae (L3-1) and (L3-2) above, n_{Lc1} is 0 or 1.

In Formula (L3-3) above, n_{Lc2} is an integer of 0 to 3.

In Formula (L3-7) above, n_{c1} is an integer of 0 to 2.

In Formula (L3-8) above, n_{c2} to n_{c5} are each independently an integer of 0 to 2.

In Formulae (L3-1) to (L3-8) above, * represents a unit binding to R^{L2} in Formula (L-1) above. The groups represented by Formulae (L3-1) to (L3-8) may have one or more substituents.

The monomer giving the structural unit (C2) is preferably a monomer wherein the lactone-containing group represented by R^{L3} above in Formula (L-1) is a group represented by Formula (L3-1) and more preferably a monomer wherein R^{Lc1} in Formula (L3-1) is a methylene group and n_{Lc1} is 0.

The content of the structural unit (C2) in the polymer (C) is preferably 20 mol % to 60 mol %, more preferably 25 mol % to 55 mol %, and still more preferably 30 mol % to 50 mol % with respect to the total structural units constituting the polymer (C). It is possible by adjusting the content of the structural unit (C2) in polymer (C) in the range above to improve the adhesiveness of the resist pattern formed from the radiation-sensitive resin composition according to the embodiment of the present invention to the substrate.

### [Structural Unit (C3)]

The acid-dissociable group-containing polymer (C) preferably has, besides the structural units (C1) described above, polar group-containing structural units (C3) additionally. The “polar group,” as used herein, is at least one group selected from the group consisting of hydroxy, carboxy, keto, sulfonamide, amino, amide, and cyano. The polymer (C), if it has the structural units (C3), contributes to improvement of the adhesiveness of the resist film formed from the radiation-sensitive resin composition to the substrate. The polymer (C) may contain structural units (C3) containing a single kind of polar group or two or more kinds of polar groups.

The polar group-containing structural unit (C3) is, for example, a structural unit represented by the following Formula ([C. 34]).

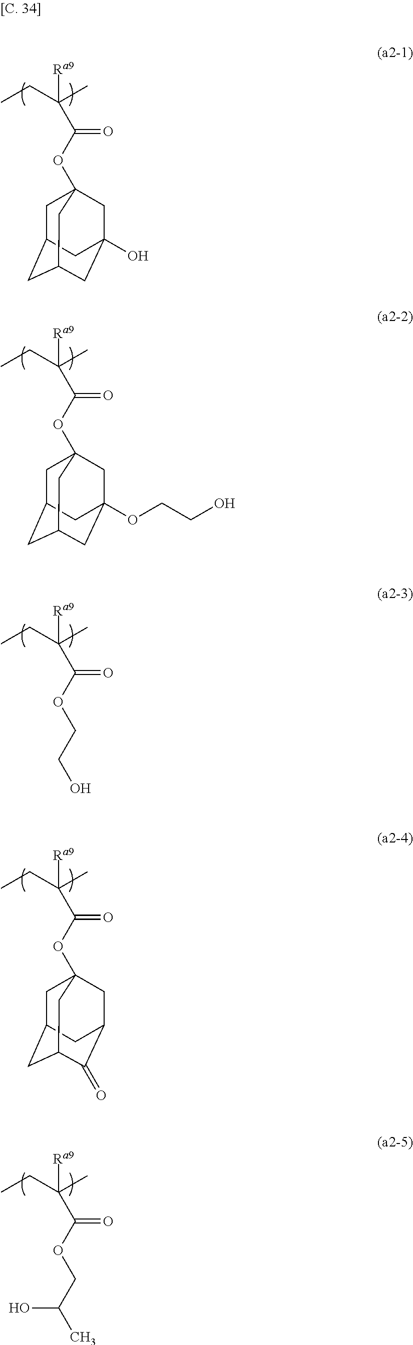

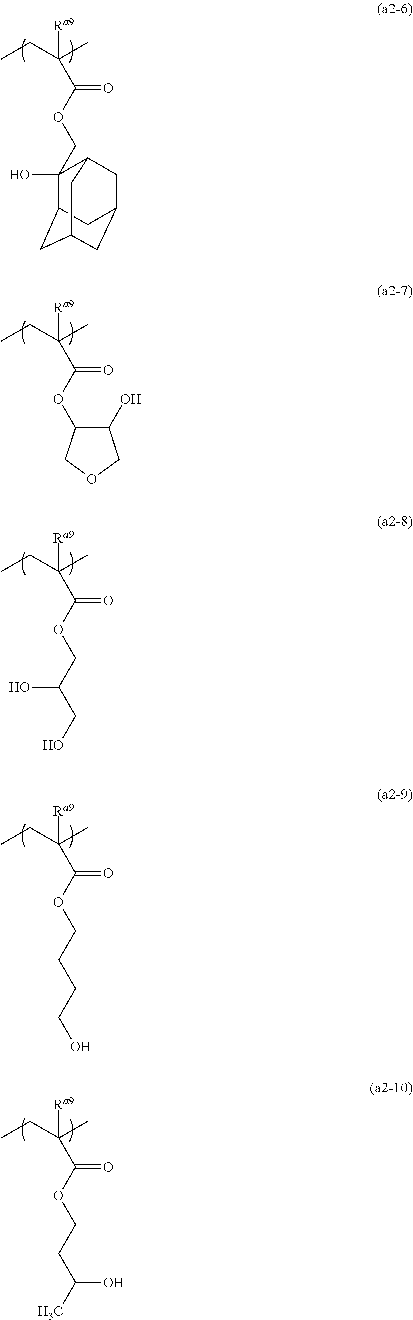

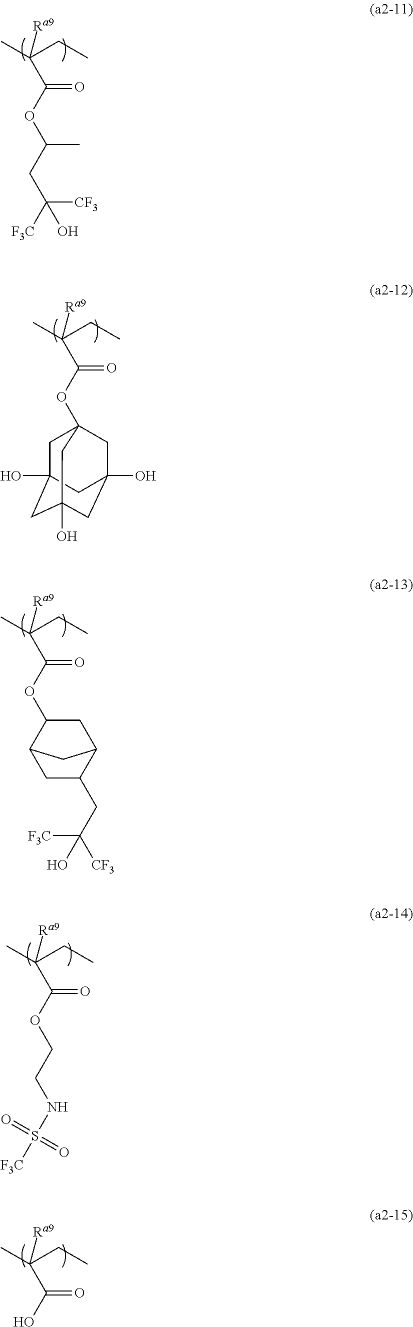

In Formula ([C. 34]) above, R^{a9} represents a hydrogen or fluorine atom or a methyl or trifluoromethyl group.

In Formula above ([C. 34]), the structural unit (C3) is preferably a structural unit represented by Formula (a2-15) above.

The content of the structural unit (C3) in polymer (C) is preferably 5 mol % to 20 mol % and more preferably 5 mol % to 10 mol % with respect to the total structural units constituting the polymer (C).

### (Synthetic Method for Polymer (C))

The polymer (C) can be synthesized, for example, by polymerizing monomers giving respective structural units in a suitable solvent using a radical polymerization initiator.

The radical polymerization initiator used in the polymerization for polymer (C) is a radical polymerization initiator similar to that used in radical polymerization for synthesis of “block copolymer (A)” described above.

The solvent used in the polymerization for polymer (C) is a solvent similar to that used in radical polymerization for synthesis of “block copolymer (A)” described above.

The reaction temperature during the polymerization for polymer (C) is normally 40° C. to 150° C. and preferably 50° C. to 120° C. The reaction period is normally 1 hour to 48 hours and preferably 1 hour to 24 hours.

The weight-average molecular weight (Mw) of the polymer (C) as polystyrene is preferably 3000 to 30000. When the Mw of the polymer (C) is in the particular range above, it is possible to obtain easily a radiation-sensitive resin composition giving a resist pattern having a favorable pattern shape with fewer development defects.

The minimum Mw of the polymer (C) is preferably 3000, more preferably 4000, and still more preferably 5000. Alternatively the maximum Mw of the polymer (C) is preferably 30000, more preferably, 25000, and still more preferably 20000.

The ratio (Mw/Mn) of the Mw of the polymer (C) to the number-average molecular weight (Mn) thereof as polystyrene is normally 1 to 3 and preferably 1 to 2.

### (Content of Polymer (C))

The content of the polymer (C) in the radiation-sensitive resin composition according to the embodiment of the present invention is normally 70 mass % or more and preferably 80 mass % or more, with respect to the total solid matter in the composition.

### <Acid Diffusion-Regulating Agent (D)>

The radiation-sensitive resin composition described above preferably contains, besides the acid-generating agent (B) described above, an acid diffusion-regulating agent (D). The acid diffusion-regulating agent (D) is a component that regulates the diffusion phenomenon of the acid generated from the acid generator (B) by photoirradiation in the resist film and suppresses unfavorable chemical reactions in the unexposed region.

The radiation-sensitive resin composition, if it contains an acid diffusion-regulating agent (D), can improve the pattern shape and the dimensional accuracy of the resist pattern formed. The acid diffusion-regulating agent (D) in the radiation-sensitive resin composition may be contained in the shape of a low-molecular weight compound of the acid diffusion-regulating agent (hereinafter, referred to also as “acid diffusion-regulating agent (D)”), in the shape as the acid diffusion control groups thereof which are introduced as part of a polymer such as block copolymer (A) or polymer (C), or in the shape in combination thereof.

Examples of the acid diffusion-regulating agents (D) include compounds represented by the following Formula (D1) (hereinafter, referred to also as “nitrogen-containing compounds (d1)”), compounds having two nitrogen atoms in the same molecule (hereinafter, referred to also as “nitrogen-containing compounds (d2)”), compounds having three or more nitrogen atoms (hereinafter, referred to also as “nitrogen-containing compounds (d3)”), amide group-containing compounds, urea compounds, nitrogen-containing heterocyclic compounds, acid-dissociable group-containing nitrogen-containing compounds, and the like.

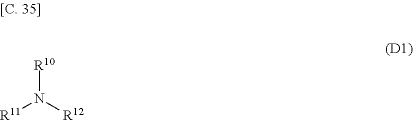

In Formula D1 above, R¹⁰ to R¹² each independently represent a hydrogen atom, a straight- or branched-chain alkyl group or a cycloalkyl group, an aryl group, or an aralkyl group. Part or all of the hydrogen atoms in the alkyl, cycloalkyl, aryl, and aralkyl groups may be substituted.

Examples of the nitrogen-containing compounds (dl) include monoalkyl amines such as n-hexylamine, dialkylamines such as di-n-butylamine, trialkylamines such as triethylamine, aromatic amines such as aniline and diisopropylaniline, and the like. Among the compounds above, aromatic amines are preferable, and diisopropylaniline is more preferable.

Examples of the nitrogen-containing compounds (d2) include ethylenediamine, N, N, N′,N′-tetramethylethylenediamine, and the like.

Examples of the nitrogen-containing compounds (d3) include polyethyleneimine, polyallylamine, polymers of dimethylaminoethylacrylamide, and the like.

Examples of the amide group-containing compounds include formamide, N-methylformamide, N, N-dimethylformamide, acetamide, N-methylacetamide, N, N-dimethylacetamide, propionamide, benzamide, pyrrolidone, N-methylpyrrolidone, and the like.

Examples of the urea compounds include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compounds include pyridines such as pyridine and 2-methylpyridine, pyrazine, pyrazole, and the like.

Examples of the acid-dissociable group-containing nitrogen-containing compounds include N-(t-butoxycarbonyl)piperidine, N-(t-butoxycarbonyl)imidazole, N-(t-butoxycarbonyl)benzimidazole, N-(t-butoxycarbonyl)-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-(t-butoxycarbonyl)-4-hydroxypiperidine, and the like.

For improvement of the sensitivity of the radiation-sensitive resin composition, the content of the acid diffusion-regulating agent (D) in the radiation-sensitive resin composition, when the acid diffusion-regulating agent (D) is an acid diffusion-regulating agent (D), is preferably 0.01 to 20 parts by mass and more preferably 0.1 to 10 parts by mass with respect to 100 parts by mass of the total of the block copolymer (A) and the polymer (C) described above.

### <Solvent (E)>

The radiation-sensitive resin composition described above normally contains a solvent (E). The solvent (E) is not particularly limited, if it can dissolve at least the block copolymer (A), the acid-generating agent (B), the polymer (C) and the acid diffusion-regulating agent (D) added as needed, and other arbitrary components.

Examples of the solvents (E) include alcohol solvents, ether solvents, ketone solvents, amide solvents, ester solvents, hydrocarbon solvents, mixtures thereof, and the like.

Examples of the alcohol solvents include monovalent alcohol solvents, polyvalent alcohol solvents, partially etherified polyvalent alcohol solvents, and the like.

Typical examples of the monovalent alcohol solvents include methanol, ethanol, straight- or branched-chain alcohols having a carbon number of 3 to 20, furfuryl alcohol, phenol, cyclohexanol, methylcyclohexanol, 3,3,5-trimethylcyclohexanol, benzyl alcohol, diacetone alcohol, and the like.

Typical examples of the polyvalent alcohol solvents include ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and the like.

Typical examples of the partially etherified polyvalent alcohol solvents include alkylene glycol monoalkyl ethers, alkylene glycol monoaryl ethers, and the like. Examples of these “alkylene” units include those having a carbon number of 2 or 3 (ethylene or propylene) and a repetition number of 1 or 2 (monoalkylene or dialkylene). Alternatively, examples of the “alkyl” units include alkyl groups having a carbon number of 1 to 6 and examples of the “aryl” units include aryl groups having a carbon number of 6 to 8. Typical examples of the partially etherified polyvalent alcohol solvents include alkoxy alcohols such as 3-methoxy butanol and the like.

Typical examples of the ether solvents include diethylether, dipropylether, dibutylether, diphenylether, and the like.

Typical examples of ketone solvents include acetone, methylethylketone, methyl-n-propylketone, methyl-n-butylketone, diethylketone, methyl-i-butylketone, methyl-n-pentylketone, ethyl-n-butylketone, methyl-n-hexylketone, di-i-butylketone, trimethylnonanone, cyclopentanone, cyclohexanone, cycloheptanone, cyclooctanone, methylcyclohexanone, 2,4-pentanedione, acetonylacetone, acetophenone, and the like.

Typical examples of the amide solvents include N,N′-dimethylimidazolidinone, N-methylformamide, N, N-dimethylformamide, N,N-diethylformamide, acetamide, N-methylacetamide, N,N-dimethylacetamide, N-methylpropionamide, N-methylpyrrolidone, and the like.

Typical examples of the ester solvent include diethyl carbonate, propylene carbonate, γ-butyrolactone, γ-valerolactone, and esters of the alcohol solvents above with carboxylic acids such as acetic acid, acetoacetic acid, lactic acid, oxalic acid, and propionic acid and the like.

Examples of the hydrocarbon solvents include aliphatic hydrocarbon solvents, aromatic hydrocarbon solvents, and the like.

Typical examples of the aliphatic hydrocarbon solvents include n-pentane, i-pentane, n-hexane, i-hexane, n-heptane, i-heptane, 2,2,4-trimethylpentane, n-octane, i-octane, cyclohexane, methylcyclohexane, and the like.

Typical examples of the aromatic hydrocarbon solvents include benzene, toluene, xylene, mesitylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and the like.

These solvents (E) may be used alone or in combination of two or more.

Among the solvents (E) above, one or more solvents selected from the group consisting of propylene glycol monoalkyl ether acetates and ketones are preferable, one or more solvents selected from the group consisting of propylene glycol monoalkyl ether acetates and cyclic ketones are more preferable, and one or more solvents selected from the group consisting of propylene glycol monomethylether acetates and cyclohexanone are more preferable, because the solvents are superior in solubilization or dispersion efficiency and make the film preparation easier.

### <Others Additives (F)>

The radiation-sensitive resin composition according to the embodiment of the present invention can contain, as needed in addition to the components above, others additives (F) such as segregation promoters, surfactants, alicyclic skeleton-containing compounds, sensitizers, and crosslinking agents. These other additives (F) different or identical in kind can be used alone or as a mixture of two or more.

### (Segregation Promoter)

The segregation promoter is a compound having an action to segregate the block copolymer (A) on the surface of the resist film more efficiently. The radiation-sensitive resin composition, if it contains the segregation promoter, improves the hydrophobicity of the resist film surface, thus reducing the defects due to liquid immersion such as watermark defects and consequently makes the content of the block copolymer (A) smaller than before. Thus, it is possible to suppress elution of the components from the resist film to the liquid-immersion solution further and to perform the liquid-immersion exposure by high-speed scanning at higher speed without deteriorating the basic properties of the resist such as LWR (Line Width Roughness), development defect, and pattern tilt resistance.

Examples of the segregation promoters include low-molecular weight compounds having a dielectric constant of 30 or more and 200 or less, a boiling point of 100° C. or higher at 1 atmospheric pressure, and the like. Examples of such compounds include lactone compounds, carbonate compounds, nitrile compounds, polyvalent alcohols, and the like.

Examples of the lactone compounds include γ-butyrolactone, valerolactone, mevalonic lactone, norbornane lactone, and the like.

Examples of the carbonate compounds include propylene carbonate, ethylene carbonate, butylene carbonate, vinylene carbonate, and the like.

Examples of the nitrile compounds include succinonitrile and the like.

Examples of the polyvalent alcohols include glycerol and the like.

The content of the segregation promoter in the radiation-sensitive resin composition is preferably 10 to 500 parts by mass and more preferably 30 to 300 parts by mass, with respect to 100 parts by mass of the total of the block copolymer (A) and the polymer (C) described above.

### (Surfactant)

The surfactant is a component that improves the coating, printing, and other properties of the radiation-sensitive resin composition described above. Examples of the surfactants include nonionic surfactants such as polyoxyethylene laurylether, polyoxyethylene stearylether, polyoxyethylene oleylether, polyoxyethylene n-octylphenylether, polyoxyethylene n-nonylphenylether, polyethylene glycol dilaurate, polyethylene glycol distearate, and the like.

The content of the surfactant in the radiation-sensitive resin composition is normally 2 parts by mass or less with respect to 100 parts by mass of the total of the block copolymer (A) and the polymer (C) described above.

### (Alicyclic Skeleton-Containing Compound)

The alicyclic skeleton-containing compound is a component that improves the dry etching resistance, the pattern shape, adhesiveness to the substrate, and the like of the resist pattern formed from the radiation-sensitive resin composition.

Examples of the alicyclic skeleton-containing compounds include adamantane derivatives such as 1-adamantanecarboxylic acid, 2-adamantanone, and t-butyl 1-adamantanecarboxylate; deoxycholic acid esters such as t-butyl deoxycholate, t-butoxycarbonylmethyl deoxycholate, and 2-ethoxyethyl deoxycholate; lithocholic acid esters such as t-butyl lithocholate, t-butoxycarbonylmethyl lithocholate, and 2-ethoxyethyl lithocholate; 3-[2-hydroxy-2,2-bis(trifluoromethyl)ethyl]tetracyclo[4.4.0.12,5.17,10]dodecane, 2-hydroxy-9-methoxycarbonyl-5-oxo-4-oxa-tricyclo[4.2.1.03,7]nonane, and the like.

The content of the alicyclic skeleton-containing compound in the radiation-sensitive resin composition is normally 50 parts by mass or less, preferably 30 parts by mass or less, with respect to 100 parts by mass of the total of the block copolymer (A) and the polymer (C) described above.

### (Sensitizer)

The sensitizer is a component that absorbs the energy of the light not absorbed by the acid-generating agent (B), transfers the energy to the acid-generating agent (B) for example in the form of radical, and thus shows an action to increase the amount of the acid generated. Thus, it improves the “apparent sensitivity” of the radiation-sensitive resin composition.

Examples of such sensitizers include carbazoles, acetophenones, benzophenones, naphthalenes, phenols, biacetyl, eosin, rose bengal, pyrenes, anthracenes, phenothiazines, and the like.

### (Crosslinking Agent)

When a radiation-sensitive resin composition is used as the negative-type radiation-sensitive resin composition, the composition may contain a compound that can crosslink an alkaline developing solution-soluble polymer in the presence of an acid (hereinafter, referred to also as “crosslinking agent”). The crosslinking agent is, for example, a compound having one or more reactive functional groups that can crosslink the alkaline developing solution-soluble polymer and the like (hereinafter, referred to also as “crosslinking functional group”).

Examples of the crosslinking functional groups include glycidylether, glycidylester, glycidylamino, methoxymethyl, ethoxymethyl, benzyloxymethyl, acetoxymethyl, benzoyloxymethyl, formyl, acetyl, vinyl, isopropenyl, (dimethylamino)methyl, (diethylamino)methyl, (dimethylolamino)methyl, (diethylolamino)methyl, morpholinomethyl, and the like.

Examples of the crosslinking agents include those described in WO 2009/51088, paragraphs [0169] to [0172].

The crosslinking agent is preferably a methoxymethyl group-containing compound and more preferably dimethoxymethylurea or tetramethoxymethylglycoluril.

The content of the crosslinking agent is preferably 5 to 95 parts by mass, more preferably 15 to 85 parts by mass, and still more preferably 20 to 75 parts by mass, with respect to 100 parts by mass of the alkaline developing solution-soluble polymer.

The additives (F) include, besides the additives above, for example, dyes, pigments, adhesion assistants, storage stabilizers, antifoams, and the like.

### [Preparation of Radiation-Sensitive Resin Composition]

The radiation-sensitive resin composition according to the embodiment of the present invention can be prepared by dissolving a block copolymer (A), an acid generator (B), and any other components added as needed such as a polymer (C) in a solvent (E), for example at a total solid matter concentration of 1 to 50 mass % or preferably 3 to 25 mass %, and filtering the solution through a filter, for example, having a pore size of about 0.02 μm.

The radiation-sensitive resin composition preferably contains a smallest amount of impurities such as halide ions and metals. At low impurity content, it is possible to further improve the sensitivity, resolution, process stability, pattern shape, and others of the radiation-sensitive resin composition. Accordingly, the polymers such as block copolymer (A) and polymer (C) contained in the radiation-sensitive resin composition are preferably purified for example by a chemical purification method such as washing or liquid-liquid extraction or by a chemical purification and a physical purification method such as ultrafiltration or centrifugation in combination.

### [Resist-Patterning Method]

The resist-patterning method according to the embodiment of the present invention comprises (1) a step of forming a resist film on a substrate using the radiation-sensitive resin composition according to the embodiment of the present invention (hereinafter, referred to also as “step (1)”), (2) a step of liquid-immersion exposing the resist film (hereinafter, referred to also as “step (2)”), and (3) a step of forming a resist pattern by developing the liquid-immersion-exposed resist film (hereinafter, referred to also as “step (3)”).

It is possible by the resist-patterning method, which uses the radiation-sensitive resin composition according to the embodiment of the present invention, to form a favorable resist pattern with fewer development defects.

### <Step (1)>

In Step (1), the radiation-sensitive resin composition described above is coated on a substrate, forming a resist film. The substrate is, for example, a substrate known in the art such as silicon wafer or aluminum-coated wafer. The application method is, for example, spin coating, cast coating, or roll coating. The film thickness of the resist film formed is preferably 10 to 1,000 nm and more preferably 10 to 500 nm.

After application of the radiation-sensitive resin composition, the solvent in the coated film may be evaporated by soft baking (SB) as needed. The SB condition may be selected appropriately according to the blending composition of the radiation-sensitive resin composition, but the SB temperature is normally 30° C. to 200° C. and preferably 50° C. to 150° C. The SB period is normally 5 to 600 seconds and preferably 10 to 300 seconds.

In the resist-patterning method, an organic or inorganic antireflective film may be formed on the substrate used, as disclosed, for example, in JP-A No. S59-93448. Alternatively, for elimination of the influence by basic impurities and the like present in environment atmosphere, for example, a protection film may be formed on the resist film, as disclosed in JP-A No. H05-188598. Further, for prevention of bleeding of for example an acid generator from the resist film during liquid-immersion exposure, for example, a protection film for liquid immersion may be formed on the resist film, as disclosed in JP-A No. 2005-352384. These technologies may be used in combination. However, when the radiation-sensitive resin composition above is used, it is possible to form a resist pattern easily on the resist film formed from the radiation-sensitive resin composition without the protection film (overcoat film) above formed on the resist film. When a resist pattern is formed on an overcoat film-free resist film, it is possible to eliminate the process for preparation of the protection film (overcoat film) and to improve the throughput.

### <Step (2)>

In Step (2), the resist film formed in Step (1) described above is subjected to liquid-immersion exposure. Normally in the liquid-immersion exposure, a reduction projector called stepper is used. The liquid-immersion exposure liquid is placed between the projection lens of the stepper and the resist film formed in Step (1), and a pattern of reticle (photomask) is projection-irradiated over a wafer, as it is contracted by the projection lens.

The liquid-immersion exposure liquid is, for example, water or a long chain or cyclic aliphatic compound. Preferably, the liquid-immersion exposure liquid is a liquid that is transparent to a light at the exposure wavelength and has a smallest possible temperature coefficient of refractive index, for maximum reduction of deformation of the optical image projected on the film.

When the exposure light source is an ArF excimer laser, the liquid used is preferably water from the viewpoints above and also from the viewpoint of easiness in procurement and handling. When water is used, an additive for reduction of the surface tension of water and for increase of surface activity may be added in a small amount. The additive is preferably a liquid that does not dissolve the resist film on wafer and shows negligible influence on the optical film formed on the bottom face of the lens. The water for use is preferably distilled water or ultrapure water.

The exposure beam used in the liquid-immersion exposure is selected appropriately, according to the kind of the acid-generating agent (B) used, from electromagnetic waves such as visible ray, ultraviolet ray, far-ultraviolet ray, and X ray and also from charged particle beams such as electron beam and alpha ray. In particular, the exposure beam for use in liquid-immersion exposure is preferably far ultraviolet ray, more preferably an ArF or KrF excimer laser (wavelength: 248 nm), and still more preferably an ArF excimer laser. The exposure condition such as exposure quantity can be determined appropriately, for example, according to the composition of the radiation-sensitive resin composition and the kinds of the additives.

In the resist-patterning method according to the embodiment of the present invention, post-exposure baking (PEB) is preferably carried out after the liquid-immersion exposure. When PEB is carried out, dissociation reaction of the acid-dissociable groups contained in the block copolymer (A) and the polymer (C) described above proceeds smoothly. The condition of PEB can be determined appropriately according to the composition of the radiation-sensitive resin composition, and the PEB temperature is normally 30° C. to 200° C. and preferably 50° C. to 170° C. The PEB period is normally 5 to 600 seconds and preferably 10 to 300 seconds.

### <Step (3)>

In Step (3), the resist film liquid-immersion-exposed in Step (2) above is developed, to give a particular resist pattern.

The developing solution used in Step (3) is, for example, an aqueous alkaline solution containing at least one alkaline compound selected from sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene, and the like. Among them, an aqueous TMAH solution is preferable.

The concentration of the aqueous alkaline solution is preferably 10 mass % or less for solubilization of the exposed region and non-solubilization of the unexposed region.

The developing solution, i.e., the aqueous alkaline solution, may contain an organic solvent added.

Examples of the organic solvents include ketones such as acetone, 2-butanone, methyl-i-butylketone, cyclopentanone, cyclohexanone, 3-methyl cyclopentanone, and 2,6-dimethylcyclohexanone; alcohols such as methanol, ethanol, n-propanol, i-propanol, n-butanol, t-butanol, cyclopentanol, cyclohexanol, 1,4-hexanediol, and 1,4-hexanedimethanol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide, and the like. These organic solvents may be used alone or in combination of two or more.

The content of the organic solvent is preferably 100 volume parts or less with respect to 100 volume parts of the aqueous alkaline solution for prevention of decrease in printing efficiency and reduction of development residue in the exposed region.

The developing solution of the aqueous alkaline solution may contain a surfactant or the like in a suitable amount. When an aqueous alkaline solution is used as the developing solution, it is preferable to wash the resist with a rinse solution and dry the resist after development. The rinse solution is preferably water and more preferably pure water or ultrapure water.

### [Block Copolymer]

The block copolymer according to the embodiment of the present invention has at least a polymer block (I) having acid-dissociable groups and a polymer block (II) having alkali-dissociable groups and water-repellency-providing moieties. The block copolymer has been described as the “block copolymer (A)” contained in the radiation-sensitive resin composition described above and thus, duplicated description is omitted.

### EXAMPLES

Hereinafter, the present invention will be described in more detail with reference to Examples. It should be understood that the Examples below are examples of the typical embodiments of the present invention and the present invention should not be construed narrowly in scope by these Examples.

### [Determination of Weight-Average Molecular Weight (Mw), Number-Average Molecular Weight (Mn), and Degree of Dispersion (Mw/Mn)]

In Examples below, Mw, Mn, and Mw/Mn were determined by gel-permeation chromatography (GPC), using GPC columns produced by Tosoh Corporation (two G2000HXL, one G3000HXL, and one G4000HXL), under the analytical condition of a flow rate of 1.0 milliliter/minute, an elution solvent of tetrahydrofuran, and a column temperature of 40° C., and using monodisperse polystyrenes as standard samples.

### [¹³C-NMR Analysis]

The content of the structural units in the copolymers prepared in Examples (mol %) was determined from the results of ¹³C-NMR analysis. The ¹³C-NMR analysis was performed, using a nuclear magnetic resonance instrument (JNM-ECX400, produced by JEOL Ltd.) and using tetrahydrofuran-d8 as the measurement solvent.

### <Polymer Synthesis>

Monomers used in synthesis of acid-dissociable group-containing polymers [C], block copolymers [A], and random copolymers [a] are shown in the following Formula ([C. 36]).

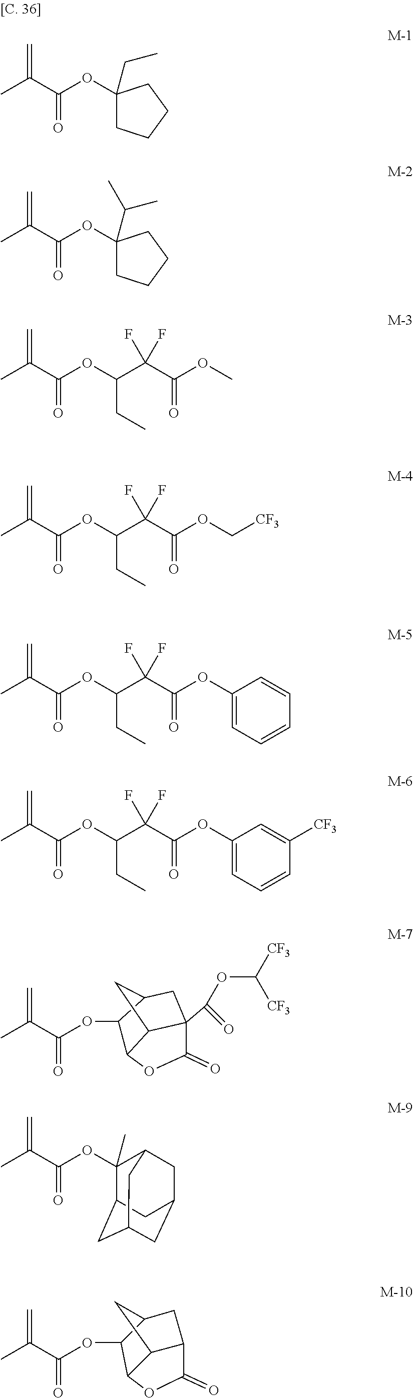

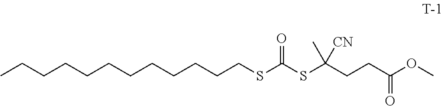 [SMILES: CCCCCCCCCCCCSC(=O)SC(C)(C#N)CCC(=O)OC]

### (1) Preparative Example of Acid-Dissociable Group-Containing Polymer [C]

Monomer (M-1): 11.93 g (65.4 mmol), monomer (M-9): 39.60 g (169 mmol), and monomer (M-10): 48.48 g (218 mmol) were dissolved in 2-butanone: 200 g. Azobisisobutyronitrile: 3.58 g (21.8 mmol) was added thereto, to give a monomer solution. 100 g of 2-butanone was placed in a 500-mL three-necked flask and the flask was purged with nitrogen for 30 minutes. The content was heated to 80° C., as it is stirred, and the monomer solution was added dropwise through a dropping funnel over 3 hours. The polymerization reaction was carried out for 6 hours after the dropwise addition started. After polymerization, the polymerization solution was cooled to 30° C. or lower by water cooling. The cooled polymerization solution was added to 2000 g of methanol and the precipitated powder was collected by filtration. The powder separated was washed twice with 400 g of methanol. The cleaned powder was dried under reduced pressure at 60° C. for 15 hours, to give a white powdery polymer (74 g, yield: 74%).

The polymer was found to be a copolymer having a Mw of 6900 and a Mw/Mn of 1.70, in which the content ratio of the recurring units derived from monomers (M-1), (M-9), and (M-10) was 14:37:49 (mol %).

### (2) Preparative Example of Block Copolymer [A]

### Synthesis of Block Copolymer (A-1)

Monomer (M-1): 20 g (90 mmol) was dissolved in 2-butanone: 20 g and chain-transfer agent (T-1): 3.734 g (9 mmol) was placed in a 500-mL three-necked flask. After purging with nitrogen for 30 minutes, the solution was heated to 80° C., as the reaction flask was stirred. A mixture solution of azobisisobutyronitrile: 0.15 g (0.9 mmol) and 2-butanone: 20 g was added dropwise to the three-necked flask over 6 hours. A mixture solution of the monomer (M-3): 85 g (360 mmol), azobisisobutyronitrile: 0.59 g (3.6 mmol), and 2-butanone: 85 g was added dropwise over 6 hours. After completion of polymerization, the polymerization solution was cooled to 30° C. or lower by water cooling, and added gradually to n-hexane: 1050 g, allowing precipitation of the solid matter. The liquid was removed from the liquid mixture by decantation, the solid matter was washed thrice with n-hexane, the resin obtained was dissolved in propylene glycol monomethylether acetate, the solution was concentrated in an evaporator, to give a block copolymer (A-1) solution: 325 g having a solid matter concentration of 20% (yield: 62%). The block copolymer (A-1) was a copolymer having a Mw of 6,500 and a Mw/Mn of 1.1, in which the content ratio of the recurring units (structural units) derived from monomers (M-1) and (M-3) was 18.8:81.2 (mol %).

### Synthesis of Block Copolymers (A-2) to (A-5)

Block copolymers (A-2) to (A-5) were prepared by a method similar to that for synthesis of block copolymer (A-1), except that the kinds and the amounts of the monomers shown in the following Table 1 were used.

### (3) Preparative Example of Random Copolymer [a]

### Synthesis of Random Copolymer (a-6)

Monomer (M-1): 16.17 g (89 mmol), monomer (M-3): 83.83 g (355 mmol), and 2-butanone: 200 g were placed and dissolved with each other in a 500-mL three-necked flask. Azobisisobutyronitrile: 3.64 g (22 mmol) was added thereto. After the flask was purged with nitrogen for 30 minutes, the content was heated to 80° C., as it is stirred. The polymerization reaction was carried out for 6 hours after the heating started. After completion of polymerization, the polymerization solution was cooled to 30° C. or lower by water cooling. The cooled polymerization solution was added gradually to n-hexane: 1500 g, allowing precipitation of the solid matter. The liquid was removed from the liquid mixture by decantation. The solid matter was washed thrice with n-hexane. The resin obtained was dissolved in propylene glycol monomethylether acetate. The solution was concentrated in an evaporator, to give a polymer (a-6) solution: 335 g having a solid matter concentration of 20% (yield: 67%). The polymer (a-6) was a copolymer having a Mw of 6,600 and a Mw/Mn of 1.5, in which the content ratio of the recurring units derived from (M-1) and (M-3) was 18.2:81.8 (mol %).

### Synthesis of Random Copolymers (a-7) to (a-8)

Random copolymers (a-7) to (a-8) were prepared by a method similar to that for synthesis of random copolymer (a-6), except that the kinds and the amounts of the monomers shown in the following Table 1 were used.

TABLE 1

| | | | | Structural | | | |
|---|---|---|---|---|---|---|---|
| Classifi- | Compo- | | | unit | | | |
| cation of | nent | Mono- | Amount | content | Yield | | Mw/ |
| copolymer | [A] | mer | (mol %) | (mol %) | (%) | Mw | Mn |
| Block | A-1 | M-1 | 20 | 18.8 | 62 | 6500 | 1.1 |
| | | M-3 | 80 | 81.2 | | | |
| | A-2 | M-2 | 20 | 18.2 | 65 | 6700 | 1.1 |
| | | M-4 | 80 | 81.8 | | | |
| | A-3 | M-1 | 20 | 18.1 | 61 | 6600 | 1.1 |
| | | M-5 | 80 | 81.9 | | | |
| | A-4 | M-2 | 20 | 18.3 | 64 | 6800 | 1.1 |
| | | M-6 | 80 | 81.7 | | | |
| | A-5 | M-1 | 20 | 18.2 | 64 | 6500 | 1.1 |
| | | M-7 | 80 | 81.8 | | | |
| Random | a-6 | M-1 | 20 | 18.2 | 67 | 6600 | 1.5 |
| | | M-3 | 80 | 81.8 | | | |
| | a-7 | M-2 | 20 | 18.3 | 65 | 6400 | 1.5 |
| | | M-4 | 80 | 81.7 | | | |
| | a-8 | M-1 | 20 | 18.6 | 63 | 6200 | 1.5 |
| | | M-6 | 80 | 81.4 | | | |

### <Preparation of the Resist Composition for Liquid-Immersion Exposure>

Components other than the acid-dissociable group-containing polymer [C], the block copolymer [A], and the random copolymer [a] constituting resist composition for liquid-immersion exposure are shown below.

### Acid Generator [B]

Compound represented by the following Formula (B-1)

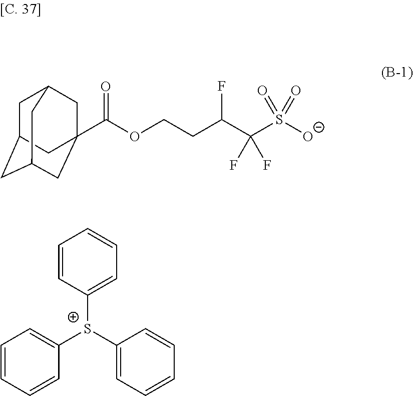 [SMILES: O=C(OCCC(F)C(F)(F)S(=O)(=O)[O-])C12CC3CC(CC(C3)C1)C2 ; c1ccc([S+](c2ccccc2)c2ccccc2)cc1]

### Acid Diffusion-Regulating Agent [D]

### Compound Represented by the Following Formula (D-1)

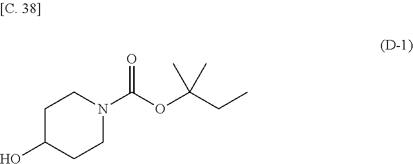

### Solvent [E]

E-1: propylene glycol monomethylether acetate
E-2: cyclohexanone
E-3: γ-butyrolactone

### Preparative Example 1

100 parts by mass of (C-1) as acid-dissociable group-containing polymer [C], 3 parts by mass of (A-1) as block copolymer [A], 8.5 parts by mass of (B-1) as acid generator [B], 2.3 parts by mass of (D-1) as acid diffusion-regulating agent [D], and 2240 parts by mass of (E-1), 960 parts by mass of (E-2), and 30 parts by mass of (E-3) as solvent [E] were mixed, to give a resist composition for liquid-immersion exposure.

### Preparative Examples 2 to 8

Each composition was prepared by a method similar to that described in Preparative Example 1, except that the kinds and the blending amounts (parts by mass) of the components blended are those shown in Table 2.

TABLE 2

| | | Composition of radiation-sensitive resin composition | | | | | | | | | |
|---|---|---|---|---|---|---|---|---|---|---|---|
| | | | | | | Acid generator | | Acid diffusion-regulating | | | |
| | | Component [C] | | Component [A] | | [B] | | agent [D] | | Solvent [E] | |
| | | | content | | content | | content | | content | | content |
| Radiation-sensitive resin | | | (part by | | (part by | | (part by | | (part by | | (part by |
| composition | | kind | mass) | kind | mass) | kind | mass) | kind | mass) | kind | mass) |
| Preparative | Example 1 | C-1 | 100 | A-1 | 3 | B-1 | 8.5 | D-1 | 1.3 | E-1/E-2/E-3 | 2240/960/30 |
| Example 1 | | | | | | | | | | | |
| Preparative | Example 2 | C-1 | 100 | A-2 | 3 | B-1 | 8.5 | D-1 | 1.3 | E-1/E-2/E-3 | 2240/960/30 |
| Example 2 | | | | | | | | | | | |
| Preparative | Example 3 | C-1 | 100 | A-3 | 3 | B-1 | 8.5 | D-1 | 1.3 | E-1/E-2/E-3 | 2240/960/30 |
| Example 3 | | | | | | | | | | | |
| Preparative | Example 4 | C-1 | 100 | A-4 | 3 | B-1 | 8.5 | D-1 | 1.3 | E-1/E-2/E-3 | 2240/960/30 |
| Example 4 | | | | | | | | | | | |
| Preparative | Example 5 | C-1 | 100 | A-5 | 3 | B-1 | 8.5 | D-1 | 1.3 | E-1/E-2/E-3 | 2240/960/30 |
| Example 5 | | | | | | | | | | | |
| Preparative | Comparative | C-1 | 100 | a-6 | 3 | B-1 | 8.5 | D-1 | 1.3 | E-1/E-2/E-3 | 2240/960/30 |
| Example 6 | Example 1 | | | | | | | | | | |
| Preparative | Comparative | C-1 | 100 | a-7 | 3 | B-1 | 8.5 | D-1 | 1.3 | E-1/E-2/E-3 | 2240/960/30 |
| Example 7 | Example 2 | | | | | | | | | | |
| Preparative | Comparative | C-1 | 100 | a-8 | 3 | B-1 | 8.5 | D-1 | 1.3 | E-1/E-2/E-3 | 2240/960/30 |
| Example 8 | Example 3 | | | | | | | | | | |

### <Evaluation>

The receding contact angle and the development defect were evaluated respectively by the following evaluation methods.

### [Determination of Receding Contact Angle]

A film having a film thickness of 80 nm was formed on an 8-inch silicon wafer, using a resist composition for liquid-immersion exposure. After soft baking (SB) at 100° C. for 60 seconds, the receding contact angle was determined on DSA-10 of KRUS under an environment at a room temperature of 23° C., a humidity of 45%, and normal pressure by the following procedure.

A DSA-10 needle was washed with acetone and isopropyl alcohol before measurement and then, water was injected to the needle. After the wafer was placed on the wafer stage, the stage height was adjusted so that the distance between the wafer surface and the tip of the needle became 1 mm or less. Water was ejected from the needle, forming a water droplet of 25 μL on the wafer. Water was withdrawn from the water droplet through the needle at a rate of 10 μL/minute for 180 seconds and the contact angle then was determined every second (a total of 180 times). After the contact angle was stabilized, a total of 20 contact angles were determined and the average thereof was calculated and used as the receding contact angle (°).

The receding contact angle after alkali development was determined according to the following procedure: A film was formed under the condition above. After SB, the film was developed with 2.38 mass % aqueous tetramethylammonium hydroxide solution for 10 seconds, using the GP nozzle of a developing device of Clean Track “ACT 8” manufactured by Tokyo Electron Limited. The resulting film was rinsed with pure water for 15 seconds and centrifuged at 2,000 rpm for separation of the solution and dried. The receding contact angle of the film obtained after drying was determined similarly. The receding contact angle obtained was used as the receding contact angle after development.

### [Evaluation of Development Defects]

A film having a film thickness of 75 nm was formed on a 12-inch silicon wafer carrying an undercoated antireflective film (manufactured by Nissan Chemical Industries, ARC66) using a photoresist composition and then soft-baked at 120° C. for 60 seconds, to give a resist film. Then, the resist film was photoirradiated with an ArF excimer laser liquid-immersion exposure device (NSR S610C, manufactured by NIKON) under the condition of NA=1.3, ratio=0.750, and Crosspole through a mask pattern having a line-and-space (1L/1S) with a width of 45 nm as the target size. After exposure, the resist film was post-exposure baked at 100° C. for 60 seconds. The resist film was then developed with 2.38 mass % aqueous tetramethylammonium hydroxide solution for 30 seconds, using a GP nozzle of a developing device of Clean Track “ACT 12” manufactured by Tokyo Electron. The resist film was rinsed with pure water for 7 seconds and centrifuged at 3,000 rpm for removal of the solution and dried, to give a resist pattern. Then, the exposure quantity forming a 1L/1S pattern with a width of 45 nm was used as the most favorable exposure quantity. An 1L/1S pattern with a line width of 45 nm was formed on the entire surface of the wafer at the most favorable exposure quantity above, to give a wafer for defect test. A scanning electron microscope (CC-4000, manufactured by Hitachi High-Technologies Corporation) was used for measurement of length. The number of defects on the wafer for defect test was then counted on KLA2810 manufactured by KLA-Tencor. The defects determined on KLA2810 were grouped into those due to the resist film and those due to external foreign materials. After the classification, the total number of the defects due to resist film was used as the value of development defects. When the total defect number is less than 1000 on the wafer, the development defect was expressed by “A,” alternatively when it is more than 1000, by “B”.

### <Results>

Results are summarized in the following Table 3.

TABLE 3

| | | TMAH development | | | |
|---|---|---|---|---|---|
| | | Receding contact angle (°) | | | |
| | | | | Difference of | |
| | PEB | | | receding contact | |
| | temper- | | After | angle between | Develop- |
| | ature | After | develop- | after SB and | ment |
| | (° C.) | SB | ment | after development | defects |
| Example 1 | 100 | 80 | 42 | 38 | A |
| Example 2 | 100 | 78 | 41 | 37 | A |
| Example 3 | 100 | 77 | 41 | 36 | A |
| Example 4 | 100 | 81 | 42 | 39 | A |
| Example 5 | 100 | 79 | 42 | 37 | A |
| Comparative | 100 | 77 | 45 | 32 | B |
| Example 1 | | | | | |
| Comparative | 100 | 77 | 45 | 32 | B |
| Example 2 | | | | | |
| Comparative | 100 | 76 | 46 | 30 | B |
| Example 3 | | | | | |

Table 3 shows that the difference of receding contact angle between after SB and after development is larger in Examples 1 to 5, wherein a block copolymer [A] was used, than in Comparative Example 1 to 3, wherein a random copolymer [a] was used as the component [A].

According to the radiation-sensitive resin composition, the resist-patterning method, and the block copolymer according to the embodiment of the present invention, it is possible, in a liquid-immersion exposure process, to improve the water repellency of the surface of the resist film significantly during photoirradiation, to decrease the reactivity of the developing solution significantly during alkali development, and consequently to reduce generation of development defects. It is thus possible to form a resist pattern that is superior in pattern shape and has a small LWR (Line Width Roughness). Therefore, the radiation-sensitive resin composition, the resist-patterning method, and the block copolymer according to the embodiment of the present invention can contribute significantly to progress of the lithographic technology that demands further reduction in size.

In addition, the radiation-sensitive resin composition according to the embodiment of the present invention shows its favorable effect, not by the kinds of the monomers constituting the polymer contained therein, but by the sequential structure of the monomers constituting the polymer. Thus, the monomers for use are not restricted, expanding the freedom in selecting the monomers. The radiation-sensitive resin composition, the resist-patterning method, and the block copolymer according to the embodiment of the present invention thus provide a lithographic technology higher in the degree of freedom.

Obviously, numerous modifications and variations of the present invention are possible in light of the above teachings. It is therefore to be understood that within the scope of the appended claims, the invention may be practiced otherwise than as specifically described herein.

1: A radiation-sensitive resin composition comprising:
(A) a block copolymer comprising:
a polymer block (I) comprising an acid-dissociable group;
a polymer block (II) comprising an alkali-dissociable group; and
a moiety contained in the polymer block (I), the polymer block (2), or both thereof, and providing water repellency; and
(B) an acid-generating agent.

2: The radiation-sensitive resin composition according to claim 1, wherein the moiety comprises a fluorine atom, a silicon atom, or both thereof.

3: The radiation-sensitive resin composition according to claim 1, wherein the moiety comprises a fluorine atom.

4: The radiation-sensitive resin composition according to claim 1, wherein the polymer block (II) comprises an alkali-dissociable group-containing structure which comprises the alkali-dissociable group, and the alkali-dissociable group-containing structure comprises a structure represented by formula (f-a), a structure represented by formula (f-b), a structure represented by formula (f-c), or combinations thereof: 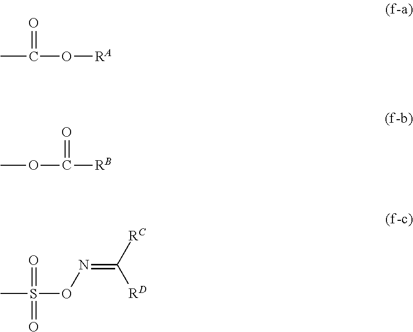
wherein, in formulae (f-a), (f-b), and (f-c): R^{A}, R^{B}, R^{C}, and R^{D} each independently represent a monovalent hydrocarbon group, in which part or all of hydrogen atoms are substituted or not substituted.

5: The radiation-sensitive resin composition according to claim 1, wherein the polymer block (II) comprises an alkali-dissociable group-containing structure which comprises the alkali-dissociable group, and the alkali-dissociable group-containing structure comprises a structural unit represented by formula (2): 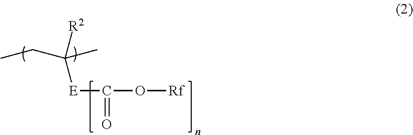
wherein, in formula (2): R² represents a hydrogen atom, a fluorine atom, or a monovalent linear hydrocarbon group having a carbon number of 1 to 4, part or all of hydrogen atoms in the linear hydrocarbon group having a carbon number of 1 to 4 being unsubstituted or substituted with a halogen atom; E represents a single bond or an (n+1)-valent group; Rf represents a monovalent linear hydrocarbon group or a monovalent aromatic hydrocarbon group, part or all of hydrogen atoms in the linear hydrocarbon group and the aromatic hydrocarbon group being unsubstituted or substituted with a fluorine atom; and n is an integer of 1 to 3, wherein in a case where n is 2 or 3, each of a plurality of Rfs is identical or different from each other.

6: The radiation-sensitive resin composition according to claim 1, wherein the block copolymer (A) is a diblock copolymer which comprises the polymer blocks (I) and the polymer block (II).

7: The radiation-sensitive resin composition according to claim 1, wherein a content of the polymer block (I) in the block copolymer (A) is from 15 to 40 mol % and a content of the polymer block (II) in the block copolymer (A) is from 60 to 85 mol %.

8: The radiation-sensitive resin composition according to claim 1, wherein the block copolymer (A) has a (meth)acrylate-derived skeleton.

9: The radiation-sensitive resin composition according to claim 1, further comprising an acid-dissociable group-containing polymer (C) which comprises an acid-dissociable group and which is other than polymers included in the block copolymer (A).

10: The radiation-sensitive resin composition according to claim 9, wherein an amount of the block copolymer (A) is from 1 to 20 parts by mass with respect to 100 parts by mass of the acid-dissociable group-containing polymer (C).

11: A resist-patterning method comprising:
(1) forming a resist film on a substrate using the radiation-sensitive resin composition according to claim 1;
(2) exposing the resist film through liquid; and
(3) forming a resist pattern by developing the exposed resist film.

12. A block copolymer comprising:
a polymer block (I) comprising an acid-dissociable group;
a polymer block (II) comprising an alkali-dissociable group; and
a moiety contained in the polymer block (I), the polymer block (II), or both thereof, and providing water repellency.
